(19) United States
(12) Patent Application Publication
(10) Pub. No.: US 2026/0006778 A1
(43) Pub. Date: Jan. 1, 2026

(54) SEMICONDUCTOR MEMORY DEVICES

(71) Applicant: Samsung Electronics Co., Ltd., Suwon-si (KR)

(72) Inventors: SUNG NAM LYU, Suwon-si (KR); SUK HOON KIM, Suwon-si (KR); HYO JUNG NOH, Suwon-si (KR); MIN WOO YANG, Suwon-si (KR); DO SUN LEE, Suwon-si (KR); JAE HUN HAN, Suwon-si (KR)

(21) Appl. No.: 19/181,995

(22) Filed: Apr. 17, 2025

Related U.S. Application Data
(63) Continuation-in-part of application No. 19/031,046, filed on Jan. 17, 2025.

(30) Foreign Application Priority Data
Jul. 1, 2024 (KR) 10-2024-0086166

(51) Int. Cl. H10B 12/00; H10D 1/68; H10D 62/17

(52) U.S. Cl. CPC H10B 12/488; H10B 12/482; H10D 1/714; H10D 62/235; H10B 12/05

(57) ABSTRACT

A semiconductor memory device includes a first word line extending on a substrate in a first direction parallel with an upper surface of the substrate; a first semiconductor pattern including a first impurity region, a first channel region, and a second impurity region, wherein the first semiconductor pattern intersects the first word line and extends in a second direction parallel with the upper surface of the substrate and intersects the first direction; a first bit line extending in a third direction perpendicular to the upper surface of the substrate, wherein the first bit line is electrically connected to the first impurity region; and a data storage element that is electrically connected to the second impurity region, wherein the first word line includes a first conductive pattern including a plurality of grains, and wherein a crystal direction of the plurality of grains is parallel with the upper surface of the substrate.

### CROSS-REFERENCE TO RELATED APPLICATIONS

This application is a continuation-in-part of U.S. patent application Ser. No. 19/031,046 filed on Jan. 17, 2025, which claims priority under 35 U.S.C. 119 to Korean Patent Application No. 10-2024-0086166, filed on Jul. 1, 2024, the disclosures of which are hereby incorporated herein by reference in its entireties.

### BACKGROUND OF THE INVENTION

The present disclosure relates to electrical devices, such as semiconductor memory devices, and more particularly, to three-dimensional semiconductor memory devices in which electrical characteristics are improved.

It may be needed to increase the degree of integration of a semiconductor device in order to meet excellent performance and low price, which may be needed by consumers. Since the degree of integration of the semiconductor device may be an important factor that determines the price of a product, an increased degree of integration may be particularly needed.

In case of a two-dimensional or planar semiconductor device of the related art, since the degree of integration of the two-dimensional or planar semiconductor device may be mainly determined by an area occupied by a unit memory cell, the two-dimensional or planar semiconductor device may be greatly affected by a level of technology for forming a fine pattern. However, since ultra-high-priced equipment may be needed for pattern miniaturization, the degree of integration of the two-dimensional semiconductor device may be increasing but still limited. Accordingly, three-dimensional semiconductor memory devices with memory cells three-dimensionally arranged have been proposed.

### SUMMARY OF THE INVENTION

An object of the present disclosure is to provide a three-dimensional semiconductor memory device in which electrical characteristics and reliability are improved.

The objects of the present disclosure are not limited to those mentioned above and additional objects of the present disclosure, which are not mentioned herein, will be clearly understood by those skilled in the art from the following description of the present disclosure.

According to an example embodiment of the present disclosure, a semiconductor device includes a first word line that extends on a substrate in a first direction that is parallel with an upper surface of the substrate; a first semiconductor pattern that includes a first impurity region, a first channel region, and a second impurity region, wherein the first semiconductor pattern intersects the first word line and extends in a second direction that is parallel with the upper surface of the substrate and intersects the first direction; a first bit line that extends in a third direction that is perpendicular to the upper surface of the substrate, wherein the first bit line is electrically connected to the first impurity region; and a data storage element that is electrically connected to the second impurity region, wherein the first word line includes a first conductive pattern including a plurality of grains, and wherein a crystal direction of the plurality of grains is parallel with the upper surface of the substrate.

According to an example embodiment of the present disclosure, a semiconductor device includes a word line that extends on a substrate in a first direction that is parallel with an upper surface of the substrate, wherein the word line includes a first conductive pattern and a second conductive pattern; a semiconductor pattern that intersects the word line and extends in a second direction that is parallel with the upper surface of the substrate and intersects the first direction, wherein the semiconductor pattern includes a first impurity region, a channel region, and a second impurity region; a bit line that is electrically connected to the first impurity region and extends in a third direction that is perpendicular to the upper surface of the substrate; and a data storage element that is electrically connected to the second impurity region, wherein a first average size of first grains of the first conductive pattern is different from a second average size of second grains of the second conductive pattern.

According to an example embodiment of the present disclosure, a semiconductor device includes a word line that extends on a substrate in a first direction that is parallel with an upper surface of the substrate; semiconductor patterns that extend in a second direction that is parallel with the upper surface of the substrate, wherein the semiconductor patterns are arranged in the first direction, and each of the semiconductor patterns includes a first impurity region, a channel region, and a second impurity region; a bit line that is electrically connected to the first impurity region; and a data storage element that is electrically connected to the second impurity region, wherein the word line intersects the semiconductor patterns and includes a first conductive pattern that has a columnar grain structure, and wherein the first direction intersects the second direction.

### BRIEF DESCRIPTION OF THE DRAWINGS

The above and other aspects and features of the present disclosure will become more apparent by describing in detail example embodiments thereof with reference to the attached drawings, in which:

FIG. 1 is a brief circuit view illustrating a cell array of a three-dimensional semiconductor memory device according to some embodiments;

FIG. 2 is an example perspective view illustrating a semiconductor memory device according to some embodiments;

FIG. 3 is a plan view illustrating a semiconductor memory device according to some embodiments;

FIG. 4 are cross-sectional views taken along lines A-A′ and B-B′ of FIG. 3;

FIG. 5 are cross-sectional views taken along lines C-C′ and D-D′ of FIG. 3;

FIG. 6 is an enlarged view illustrating a region X of FIG. 4;

FIG. 7 is a schematic view illustrating a shape of a grain of a cut surface taken along a second direction from a word line of FIG. 6;

FIGS. 8 and 9 are views illustrating a semiconductor memory device according to some embodiments;

FIG. 10 is a schematic view illustrating a shape of a grain of a cut surface taken along a second direction from a word line of FIGS. 8 and 9;

FIGS. 11 and 12 are views illustrating a semiconductor memory device according to some embodiments;

FIGS. 13 to 15 are views illustrating a semiconductor memory device according to some embodiments;

FIG. 16 is a view illustrating a semiconductor memory device according to some embodiments;

FIGS. 17 to 19 are views illustrating a semiconductor memory device according to some embodiments;

FIGS. 20 to 23 are views illustrating a semiconductor memory device according to some embodiments;

FIGS. 24 to 55 are views illustrating a method of fabricating a semiconductor memory device according to some embodiments;

FIGS. 56 and 57 are views illustrating a method of fabricating a semiconductor memory device according to some embodiments; and

FIGS. 58 and 59 are example perspective views illustrating a semiconductor memory device according to some embodiments.

### DETAILED DESCRIPTION OF THE INVENTION

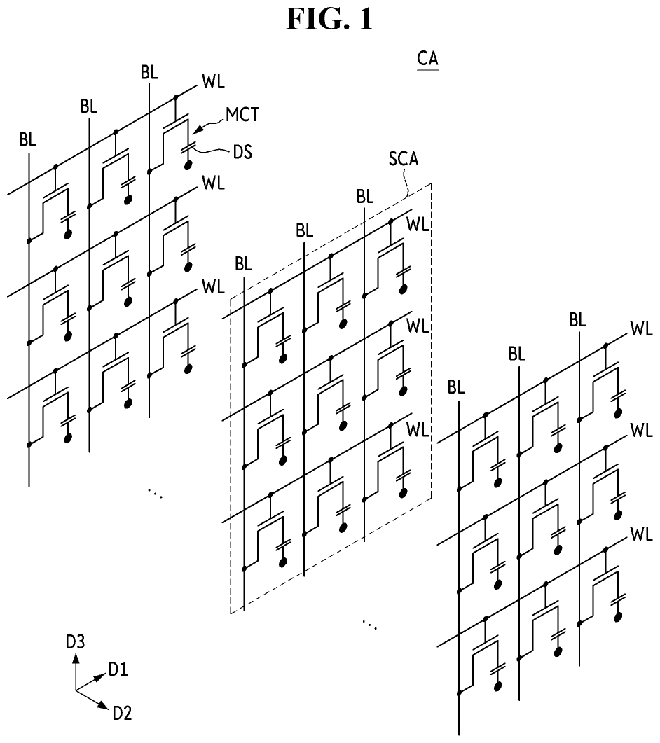

FIG. 1 is a brief circuit view illustrating a cell array of a three-dimensional semiconductor memory device according to some embodiments.

Referring to FIG. 1, a cell array CA of a three-dimensional semiconductor device according to some embodiments may include a plurality of sub-cell arrays SCA. The sub-cell arrays SCA may be arranged along a second direction D2.

Each of the sub-cell arrays SCA may include a plurality of bit lines BL, a plurality of word lines WL, and a plurality of memory cell transistors MCT. One memory cell transistor MCT may be disposed between (e.g., intersection of) one word line WL and one bit line BL.

The bit lines BL may be conductive patterns (e.g., metallic conductive lines) extended in a vertical direction (i.e., a third direction D3) from a substrate. The bit lines BL in one sub-cell array SCA may be arranged in a first direction D1. The bit lines BL adjacent to each other may be spaced apart from each other in the first direction D1.

The word lines WL may be conductive patterns (e.g., metallic conductive lines) stacked on the substrate in the third direction D3. Each of the word lines WL may be extended in the first direction D1. The word lines WL adjacent to each other may be spaced apart from each other in the third direction D3.

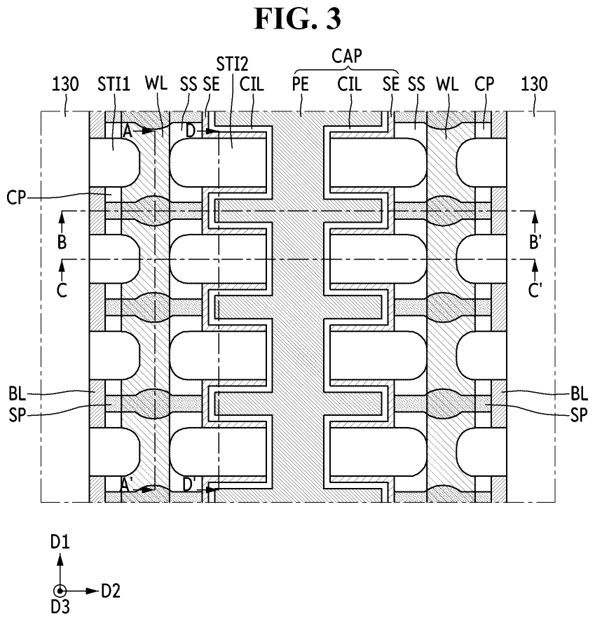

A gate of the memory cell transistor MCT may be (electrically) connected to the word line WL, and a first source/drain of the memory cell transistor MCT may be (electrically) connected to the bit line BL. A second source/drain of the memory cell transistor MCT may be (electrically) connected to a data storage element DS. For example, the data storage element DS may be a capacitor. The second source/drain of the memory cell transistor MCT may be (electrically) connected to a storage electrode (SE of FIG. 3) of the capacitor.

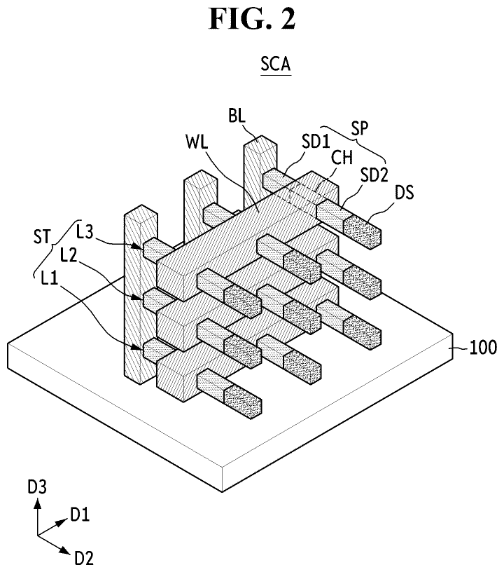

FIG. 2 is an example perspective view illustrating a semiconductor memory device according to some embodiments.

Referring to FIGS. 1 and 2, one of the plurality of sub-cell arrays SCA described using FIG. 1 may be disposed on a substrate 100.

The substrate 100 may be a bulk silicon or a silicon-on-insulator (SOI). In some embodiments, the substrate 100 may be a silicon substrate, or may include another material, for example, silicon germanium on insulator (SGOI), indium antimony, lead tellurite compound, indium arsenide, indium phosphide, gallium arsenide and/or gallium antimony, but is not limited thereto. The following description will be based on that the substrate 100 is a substrate containing silicon.

In this case, the first direction D1, the second direction D2 and the third direction D3 may intersect (cross or overlap) one another. Also, the first direction D1 and the second direction D2 may be parallel with an upper surface of the substrate 100, and the third direction D3 may be perpendicular to the upper surface of the substrate 100. Spatially relative terms, such as “beneath,” “below,” “lower,” “under,” “above,” “upper,” and the like, may be used herein for ease of explanation to illustrate one element or feature's relationship to another element or feature as illustrated in the drawings. It will be understood that the spatially relative terms are intended to encompass different orientations of the device in use or in operation, in addition to the orientation depicted in the drawings. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly. Directional terms, such as “parallel”, “horizontal”, “perpendicular”, “vertical”, and the like, may be used herein for ease of explanation to illustrate the directions of elements as illustrated in the drawings. It will be understood that the directional terms may include not only accurate directions but also general directions and overall directions.

A stacked structure ST, which includes first, second, and third layers L1, L2, and L3 may be disposed on the substrate 100. The first, second, and third layers L1, L2, and L3 of the stacked structure ST may be stacked to be spaced apart from one another in a direction perpendicular to the upper surface of the substrate 100 (i.e., the third direction D3). In some embodiments, the first, second, and third layers L1, L2, and L3 of the stacked structure ST may be stacked to be spaced apart from one another in a thickness direction (i.e., the third direction D3) of the substrate 100. The number of layers L1, L2, and L3 of the stacked structure ST is not limited to the above example.

In some embodiments, each of the first, second, and third layers L1, L2, and L3 may include a plurality of semiconductor patterns SP, a plurality of data storage elements DS, and a word line WL.

The semiconductor pattern SP may have, for example, a line shape or a bar shape, which is extended in the second direction D2. The plurality of semiconductor patterns SP positioned at the same level may be arranged in the first direction D1. For example, the semiconductor patterns SP of the first layer L1 may be positioned at the same level and arranged in the first direction D1. The term, “level”, may be a relative location (e.g., distance) from the upper surface of the substrate 100 in a vertical direction (e.g., the third direction D3). A farther distance from the upper surface of the substrate 100 may be referred to as a higher level. A closer distance from the upper surface of the substrate 100 may be referred to as a lower level. The semiconductor pattern SP may include a semiconductor material such as silicon, germanium, and/or silicon-germanium. For example, the semiconductor pattern SP may include, for example, polysilicon, polysilicon germanium, single crystal silicon and/or single crystal silicon-germanium.

Each semiconductor pattern SP may include a channel region CH, a first impurity region SD1 and a second impurity region SD2. The channel region CH may be interposed between the first and second impurity regions SD1 and SD2. The channel region CH may correspond to a channel of the memory cell transistor MCT described with reference to FIG. 1. The first and second impurity regions SD1 and SD2 may correspond to the first source/drain and the second source/drain of the memory cell transistor MCT described with reference to FIG. 1, respectively.

The first and second impurity regions SD1 and SD2 may be regions doped with impurities in the semiconductor pattern SP. Therefore, the first and second impurity regions SD1 and SD2 may have n-type or p-type conductivity. The first impurity region SD1 may be formed to be adjacent to a first end of the semiconductor pattern SP, and the second impurity region SD2 may be formed to be adjacent to a second end of the semiconductor pattern SP. The second end may be opposite to the first end in the second direction D2.

The first impurity region SD1 may be formed to be adjacent to the bit line BL. The first impurity region SD1 may be (electrically) connected to the bit line BL. The second impurity region SD2 may be formed to be adjacent to the data storage element DS. The second impurity region SD2 may be (electrically) connected to the data storage element DS.

The data storage elements DS may be memory elements capable of storing data. Each of the data storage elements DS may be a memory element using a capacitor, a memory element using a magnetic tunnel junction pattern or a memory element using a variable resistor containing a phase change material, but is not limited thereto. For example, each of the data storage elements DS may be a capacitor.

The word line WL may have a line shape or a bar shape, which is extended in the first direction D1. The word lines WL may be stacked to be spaced apart from each other along the third direction D3. The word line WL may be disposed on at least a portion of an outer circumferential surface of (may extend around) the channel region CH of the semiconductor pattern SP. The word line WL may be extended in the first direction D1 while crossing (intersecting or overlapping) the semiconductor pattern SP within one layer (from among the first, second, and third layers L1, L2, and L3).

In some embodiments, the word line WL may be extended in the first direction D1, and may be disposed on each of the semiconductor patterns SP disposed to be spaced apart from each other in the first direction D1 at the same level. The word line WL may be extended in the first direction D1 and may cross (e.g., extend around) each of the semiconductor patterns SP disposed to be spaced apart from each other in the first direction D1 at the same level (from among the first, second, and third layers L1, L2, and L3). A width of the word line WL in the first direction D1 may be greater than a width of the semiconductor pattern SP (e.g., a width of each of the semiconductor patterns SP) in the first direction D1.

For example, the plurality of semiconductor patterns SP of the first layer L1 may be arranged in the first direction D1, each bit line BL may be (electrically) connected to each semiconductor pattern SP of the first layer L1, and the word line WL of the first layer L1 may be extended in the first direction D1 to cross (e.g., extend around) the channel region CH of each semiconductor pattern SP of the first layer L1.

In some embodiments, the memory cell transistor MCT may be a gate-all-around transistor in which the word line WL extends around (e.g., at least partially surrounds) the channel region CH. The word line WL may extend around (e.g., at least partially surround) the outer circumferential surface of the channel region CH. The word line WL may be extended in the first direction D1 to extend around (e.g., at least partially surround) the channel region CH of each of the semiconductor patterns SP disposed to be spaced apart from each other in the first direction D1 at the same level.

The word line WL may include a conductive material. For example, the word line WL may include a doped semiconductor material (doped silicon, doped silicon-germanium, doped germanium, etc.), a conductive metal nitride (titanium nitride, tantalum nitride, etc.), metal (tungsten, titanium, tantalum, etc.) and/or a metal-semiconductor compound (tungsten silicide, cobalt silicide, titanium silicide, etc.), but is not limited thereto.

The plurality of bit lines BL extended in the vertical direction (i.e., the third direction D3) may be provided on the substrate 100. Each bit line BL may have a line shape or a column shape, which is extended in the third direction D3. The bit lines BL may be arranged along the first direction D1. Each bit line BL may be (electrically) connected to the first impurity region SD1 of the semiconductor patterns SP that are vertically stacked.

The bit line BL may include a conductive material, for example, a doped semiconductor material, a conductive metal nitride, metal and/or a metal-semiconductor compound, but is not limited thereto.

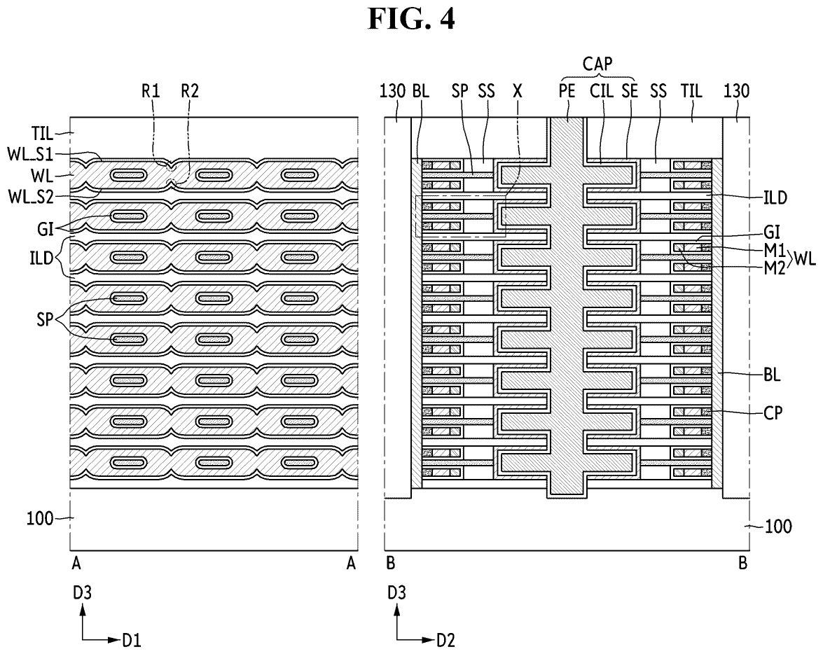

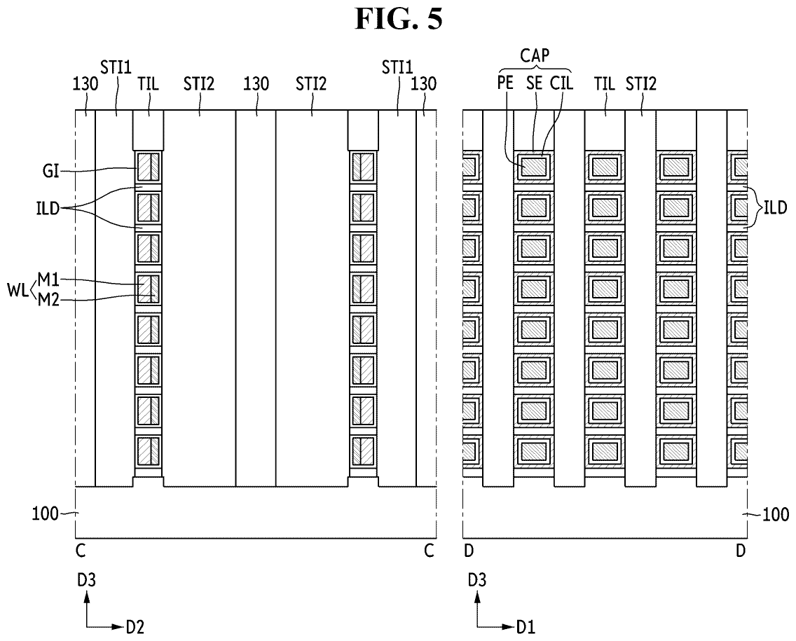

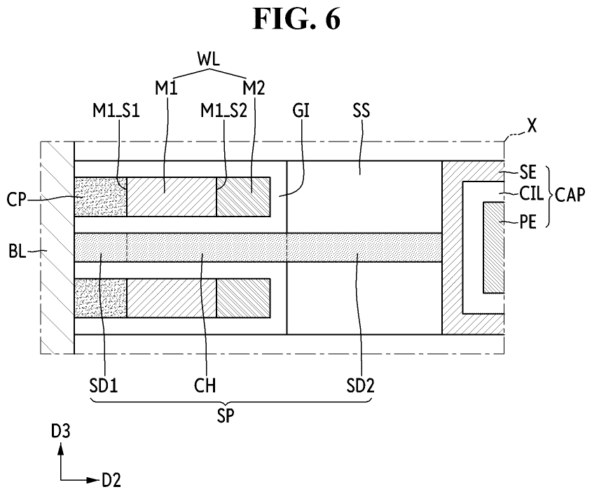

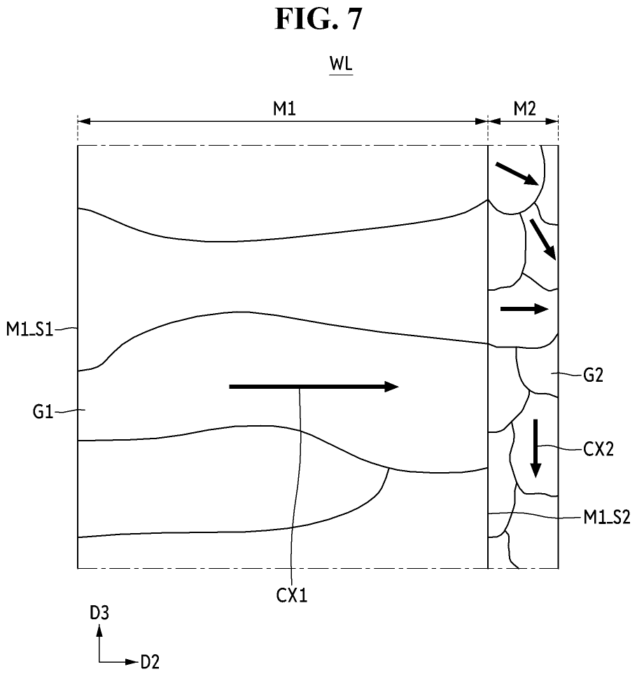

FIG. 3 is a plan view illustrating a semiconductor memory device according to some embodiments. FIG. 4 is cross-sectional views taken along lines A-A′ and B-B′ of FIG. 3. FIG. 5 is cross-sectional views taken along lines C-C′ and D-D′ of FIG. 3. FIG. 6 is an enlarged view illustrating a region X of FIG. 4. FIG. 7 is a schematic view illustrating a shape of a grain of a cut surface taken along a second direction from a word line of FIG. 6. For reference, FIG. 3 may show a view of a portion of the sub-cell array SCA of the semiconductor memory device described with reference to FIG. 1. For convenience of description, a redundant portion of that described with reference to FIGS. 1 and 2 may be briefly described, and the description may be mainly based on differences from the description of FIGS. 1 and 2.

Referring to FIGS. 3 to 7, a semiconductor memory device according to some embodiments may include a substrate 100, an interlayer insulating layer ILD, a semiconductor pattern SP, a bit line BL, a word line WL, a gate insulating layer GI, a capping insulating pattern CP, a spacer insulating pattern SS, first and second separation insulating patterns STI1 and STI2, a buried insulating pattern 130 and a capacitor CAP.

A plurality of interlayer insulating layers ILD may be disposed on the substrate 100. Each of the interlayer insulating layers ILD may be disposed to be spaced apart from each other in the third direction D3.

The interlayer insulating layer ILD may include an insulating material. For example, the interlayer insulating layer ILD may include a silicon oxide layer, a silicon nitride layer, a silicon oxynitride layer, a carbon-containing silicon oxide layer, a carbon-containing silicon nitride layer, and/or a carbon-containing silicon oxynitride layer. For example, the interlayer insulating layer ILD may include a silicon oxide layer.

A plurality of semiconductor patterns SP may be disposed between the interlayer insulating layers ILD adjacent to each other in the third direction D3. The respective semiconductor patterns SP may be disposed to be spaced apart from each other in the third direction D3. The plurality of semiconductor patterns SP may be disposed to be spaced apart from each other in the third direction D3 on the substrate 100. The interlayer insulating layer ILD may be disposed between the semiconductor patterns SP adjacent to each other in the third direction D3.

Each of the semiconductor patterns SP may be extended in the second direction D2. The interlayer insulating layer ILD may be more protruded in the second direction D2 than the semiconductor pattern SP. The first impurity region SD1 of the semiconductor pattern SP may be (electrically) connected to the bit line BL. The second impurity region SD2 of the semiconductor pattern SP may be (electrically) connected to the storage electrode SE (of the capacitor CAP). In some embodiments, the capacitor CAP may correspond to the data storage element DS in FIGS. 1 and 2.

The bit line BL may be extended in the third direction D3 on the substrate 100. The bit line BL may be (electrically) connected to the plurality of semiconductor patterns SP spaced apart from each other in the third direction D3.

The word line WL may be disposed between the interlayer insulating layers ILD adjacent to each other in the third direction D3. The word line WL may include a first surface WL_S1 and a second surface WL_S2, which are opposite to each other in the third direction D3.

In some embodiments, at least one of the first surface WL_S1 or the second surface WL_S2 of the word line WL may include recesses R1 and R2 recessed into the inside (e.g., recessed toward the central portion in the third direction D3) of the word line WL. The recesses R1 and R2 may be disposed between the semiconductor patterns SP adjacent to each other in the first direction D1. For example, the first surface WL_S1 may include the first recess R1 recessed toward the second surface WL_S2. The second surface WL_S2 may include the second recess R2 recessed toward the first surface WL_S1.

In some embodiments, the semiconductor pattern SP may have a rounded corner. The word line WL may be extended along the periphery (e.g., the circumference or perimeter) of the semiconductor pattern SP.

The gate insulating layer GI may be disposed between the word line WL and the semiconductor pattern SP and between the word line WL and the interlayer insulating layer ILD. The gate insulating layer GI may be extended along upper and lower surfaces of the word line WL and one sidewall of the word line WL, which is extended in the third direction D3 and adjacent to the spacer insulating pattern SS.

The gate insulating layer GI may include at least one of, for example, a high dielectric constant insulating layer, a silicon oxide layer, a silicon nitride layer or a silicon oxynitride layer.

The capping insulating pattern CP may be disposed between the first impurity region SD1 of the semiconductor pattern SP and the interlayer insulating layer ILD. The capping insulating pattern CP may be disposed on upper and lower surfaces of the semiconductor pattern SP. The capping insulating pattern CP may spatially separate the bit line BL from the word line WL. The gate insulating layer GI may be interposed between the capping insulating pattern CP and the interlayer insulating layer ILD and between the capping insulating pattern CP and the semiconductor pattern SP.

The spacer insulating pattern SS may be disposed between the second impurity region SD2 of the semiconductor pattern SP and the interlayer insulating layer ILD. The spacer insulating pattern SS may be disposed on the upper and lower surfaces of the semiconductor pattern SP. The spacer insulating pattern SS may be spaced apart from the word line WL with the gate insulating layer GI interposed therebetween. The gate insulating layer GI may be interposed between the spacer insulating pattern SS and the interlayer insulating layer ILD and between the spacer insulating pattern SS and the semiconductor pattern SP.

Each of the capping insulating pattern CP and the spacer insulating pattern SS may include, for example, a silicon oxide layer, a silicon nitride layer, a silicon oxynitride layer, a carbon-containing silicon oxide layer, a carbon-containing silicon nitride layer, and/or a carbon-containing silicon oxynitride layer.

The first and second separation insulating patterns STI1 and STI2 may be disposed on the substrate 100. The first separation insulating pattern STI1 may be disposed between bit lines BL adjacent to each other in the first direction D1. The second separation insulating pattern STI2 may be disposed between the storage electrodes SE adjacent to each other in the first direction D1.

The buried insulating pattern 130 may be disposed on the substrate 100. The buried insulating pattern 130 may be on (e.g., may cover or overlap in the second direction D2) a sidewall of the bit line BL and a sidewall of the first separation insulating pattern STI1.

Each of the first and second separation insulating patterns STI1 and STI2 and the buried insulating pattern 130 may include (e.g., may be formed of), for example, insulating materials, such as silicon oxide or silicon oxynitride. The first and second separation insulating patterns STI1 and STI2 and the buried insulating pattern 130 may be formed using spin on glass (SOG) technology.

In the embodiment, the data storage element (DS of FIG. 2) may include a capacitor CAP. The capacitor CAP may include a capacitor dielectric layer CIL, a plurality of storage electrodes SE and a plate electrode PE. Each capacitor CAP may include a storage electrode SE, a capacitor dielectric layer CIL and a plate electrode PE, which are disposed between the interlayer insulating layers ILD. Each capacitor CAP may be defined by each storage electrode SE.

Each storage electrode SE may be disposed between the interlayer insulating layers ILD adjacent to each other in the third direction D3. The storage electrodes SE included in each capacitor CAP may be separated from each other. The storage electrodes SE adjacent to each other in the third direction D3 may be separated from each other by the interlayer insulating layer ILD.

The capacitor dielectric layer CIL may be disposed on the storage electrode SE. The capacitor dielectric layer CIL may be (at least partially) extended along a profile of the plurality of storage electrodes SE. The plate electrode PE may be disposed on the capacitor dielectric layer CIL. The capacitor dielectric layer CIL and the plate electrode PE may be sequentially disposed on the storage electrode SE.

The capacitor dielectric layer CIL and the plate electrode PE, which are included in each capacitor CAP, may be (electrically) connected to each other.

Each of the storage electrode SE and the plate electrode PE may include, for example, a doped semiconductor material, a conductive metal nitride (e.g., titanium nitride, tantalum nitride, niobium nitride and/or tungsten nitride), metal (e.g., ruthenium, iridium, titanium, niobium, tungsten, cobalt, molybdenum and/or tantalum) and/or a conductive metal oxide (e.g., iridium oxide and/or niobium oxide), but is not limited thereto. For example, the storage electrode SE may include a conductive metal nitride, metal, and a conductive metal oxide. The conductive metal nitride, the metal, and the conductive metal oxide may be included in a metallic conductive layer.

The capacitor dielectric layer CIL may include, for example, a high dielectric constant material (e.g., hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate and/or their combination). In the semiconductor memory device according to some embodiments, the capacitor dielectric layer CIL may include a stacked layer structure in which zirconium oxide, aluminum oxide, and zirconium oxide are sequentially stacked. In the semiconductor memory device according to some embodiments, the capacitor dielectric layer CIL may include hafnium (Hf).

Referring to FIGS. 6 and 7, in some embodiments, the word line WL may include a first conductive pattern M1 and a second conductive pattern M2. The second conductive pattern M2 may be disposed on the first conductive pattern M1. The first conductive pattern M1 may be disposed between the bit line BL and the second conductive pattern M2 (in the second direction D2). The first conductive pattern M1 may be disposed between the capping insulating pattern CP and the second conductive pattern M2 (in the second direction D2).

A shape of a first grain G1 of the first conductive pattern M1 may be different from a shape of a second grain G2 of the second conductive pattern M2.

The first conductive pattern M1 may include a plurality of first grains G1. A crystal direction CX1 of the first grains G1 may be a direction (generally) parallel with the upper surface of the substrate 100. For example, the overall direction of the crystal direction CX1 of the first grains G1 may be parallel with the upper surface of the substrate 100. The crystal direction CX1 of the first grains G1 may be the same as the extended direction of the semiconductor pattern SP. The crystal direction CX1 of the first grains G1 may be the second direction D2. The first grains G1 may be aligned in the second direction D2. The first conductive pattern M1 may have a crystal structure that includes columnar grains G1 (the first grains G1) extended lengthwise in the second direction D2. For example, the first grains G1 may have shapes (generally) elongated in the second direction D2.

The second conductive pattern M2 may include a plurality of second grains G2. The second grains G2 may have a random crystal direction CX2. The second grains G2 may be aligned in a random direction. The second conductive pattern M2 may have a crystal structure that includes random grains G2 (the second grains G2). For example, the second grains G2 may have shapes elongated in various directions, respectively.

An average grain size of the first conductive pattern M1 may be different from that of the second conductive pattern M2. The average grain size of the first conductive pattern M1 may be greater (larger) than the average grain size of the second conductive pattern M2. The average grain size of the first conductive pattern M1 may be an average value of a size of the first grain G1 in the second direction D2, and the average grain size of the second conductive pattern M2 may be an average value of a size of the second grain G2 in the second direction D2. The size of the first grain G1 in the second direction D2 may be greater (larger) than that of the second grain G2 in the second direction D2.

For example, the first grains G1 of the first conductive pattern M1 may be formed through a bottom-up growth method. A direction in which the first grains G1 are grown may be easily analyzed through analysis (for example, transmission electron microscope (TEM) or precession electron diffraction (PED)) of the grains of the first conductive pattern M1 and the second conductive pattern M2.

The first conductive pattern M1 may include a first surface M1_S1 and a second surface M1_S2, which are opposite to each other in the second direction D2. The capping insulating pattern CP may be disposed on the first surface M1_S1, and the spacer insulating pattern SS may be disposed on the second surface M1_S2. In some embodiments, the second conductive pattern M2 may be on the second surface M1_S2 of the first conductive pattern M1.

At least one of the plurality of first grains G1 may be extended from the first surface M1_S1 to the second surface M1_S2 of the first conductive pattern M1. A length (height) of at least one of the plurality of first grains G1 in the second direction D2 may be the same as (equal to) a length (height) of the first conductive pattern M1 in the second direction D2. For example, at least one of the plurality of first grains G1 may extend from the first surface M1_S1 to the second surface M1_S2 of the first conductive pattern M1 in the second direction D2 without crossing or intersecting another grain of the plurality of first grains G1.

In some embodiments, the first conductive pattern M1 and the second conductive pattern M2 may include their respective materials different from each other.

In some embodiments, the first conductive pattern M1 and the second conductive pattern M2 may include the same material. In this case, since the shape of the first grain G1 of the first conductive pattern M1 is different from that of the second grain G2 of the second conductive pattern M2, a boundary between the first conductive pattern M1 and the second conductive pattern M2 may be distinguished.

For example, the first conductive pattern M1 may include a conductive material that enables selective growth. For example, the first conductive pattern M1 and the second conductive pattern M2 may include, for example, TiN, TiSiN, TiAlC, TiAlN, Mo, W, Ta, TaN, LaN, Al, Cu, Ru, and/or their compound.

In the semiconductor memory device according to some embodiments, the word line WL may include a first conductive pattern M1 that includes a first grain G1 having a crystal direction in the second direction D2 and a relatively large (a greater) size. Therefore, the number of grain boundaries in the word line WL (e.g., in the first conductive pattern M1) is reduced, so that the number of scattering times of electrons applied to the word line WL in the grain boundary may be reduced, and resistance of the word line WL may be reduced. As a result, performance and reliability of the semiconductor memory device may be improved.

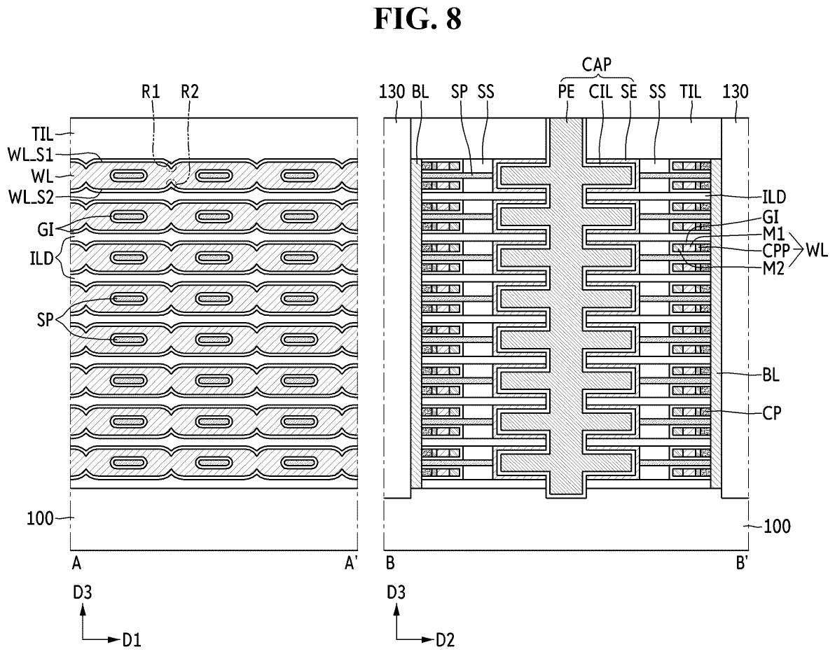

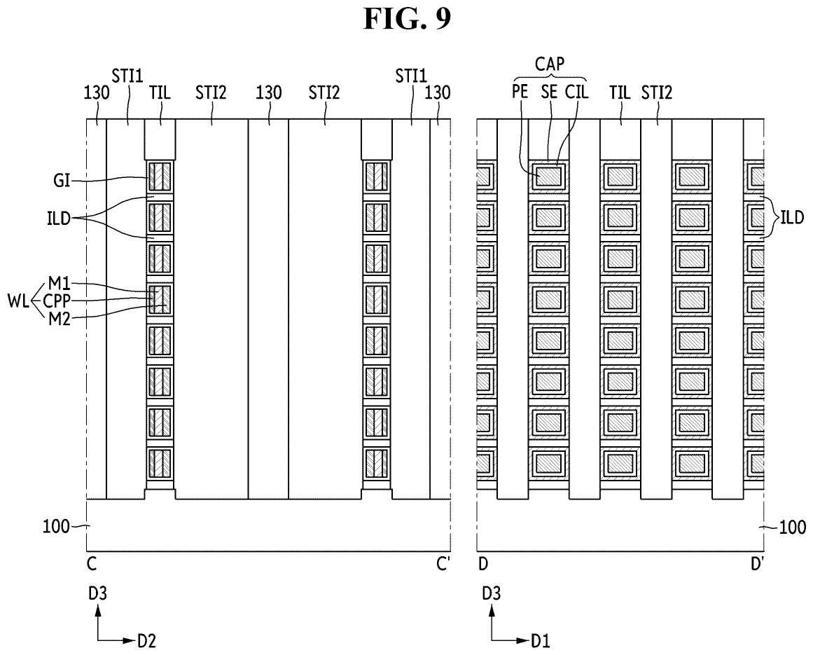

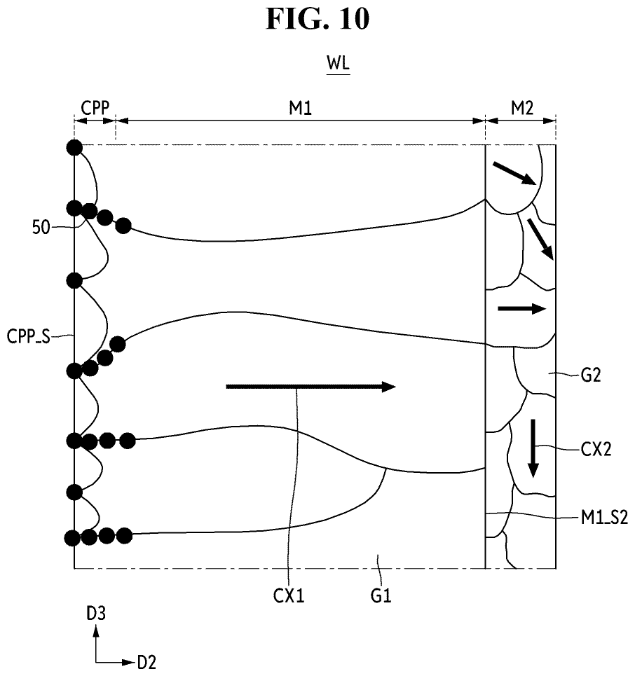

FIGS. 8 and 9 are views illustrating a semiconductor memory device according to some embodiments. FIG. 10 is a schematic view illustrating a shape of a grain of a cut surface taken along a second direction from a word line of FIGS. 8 and 9. For reference, FIG. 8 is a cross-sectional view taken along lines A-A′ and B-B′ of FIG. 3. FIG. 9 is a cross-sectional view taken along lines C-C′ and D-D′ of FIG. 3. For convenience of description, the description may be based on differences from that described with reference to FIGS. 1 to 7.

Referring to FIGS. 8 and 9, in the semiconductor memory device according to some embodiments, the word line WL may further include a capping pattern CPP. The capping pattern CPP may be disposed between the capping insulating pattern CP and the first conductive pattern M1.

The capping pattern CPP may include at least one of, for example, metal silicide or metal silicon nitride.

Referring to FIG. 10, in some embodiments, a boundary between the capping pattern CPP and the first conductive pattern M1 may not be distinguished. A grain of the capping pattern CPP may be connected to the first grain G1 of the first conductive pattern M1. A boundary of the grain of the capping pattern CPP may be connected to a boundary of the first grain G1 of the first conductive pattern M1 to form a continuous boundary. A shape of the grain of the crystal pattern CPP may be the same as a shape of the first grain G1 of the first conductive pattern M1.

The capping pattern CPP and the first conductive pattern M1 may include the same first grains G1. Each of the capping pattern CPP and the first conductive pattern M1 may include the first grains G1. The first grains G1 in the first region may constitute the first conductive pattern M1, and the first grain G1 in the second region may constitute the capping pattern CPP. At least one of the first grains G1 may be extended from the first conductive pattern M1 to the capping pattern CPP. That is, a portion of one of the first crystal grains G1 may constitute the first conductive pattern M1 and the other portion thereof may constitute the capping pattern CPP.

The capping pattern CCP may include silicon atoms 50. The silicon atoms 50 may be positioned at a boundary between a third surface CPP_S of the capping pattern CPP and the first grain G1. A size of the first grain G1 may be reduced as the first grain becomes adjacent to the third surface CPP_S of the capping pattern CPP. An average grain size of the capping pattern CPP may be smaller than the average grain size of the first conductive pattern M1. The average grain size of the capping pattern CPP may be an average value of the size of the first grain G1 of the capping pattern CPP in the second direction D2. The third surface CPP_S of the capping pattern CPP may be directed toward the capping insulating pattern (CP of FIG. 8).

Unlike the example shown in FIG. 10, in some other embodiments, the boundary between the capping pattern CPP and the first conductive pattern M1 may be distinguished. The shape of the grain of the capping pattern CPP may be different from the shape of the grain G1 of the first conductive pattern M1. The grain of the capping pattern CPP may not be connected to the grain G1 of the first conductive pattern M1. The boundary of the grain of the capping pattern CPP and the boundary of the grain G1 of the first conductive pattern M1 may be discontinuous.

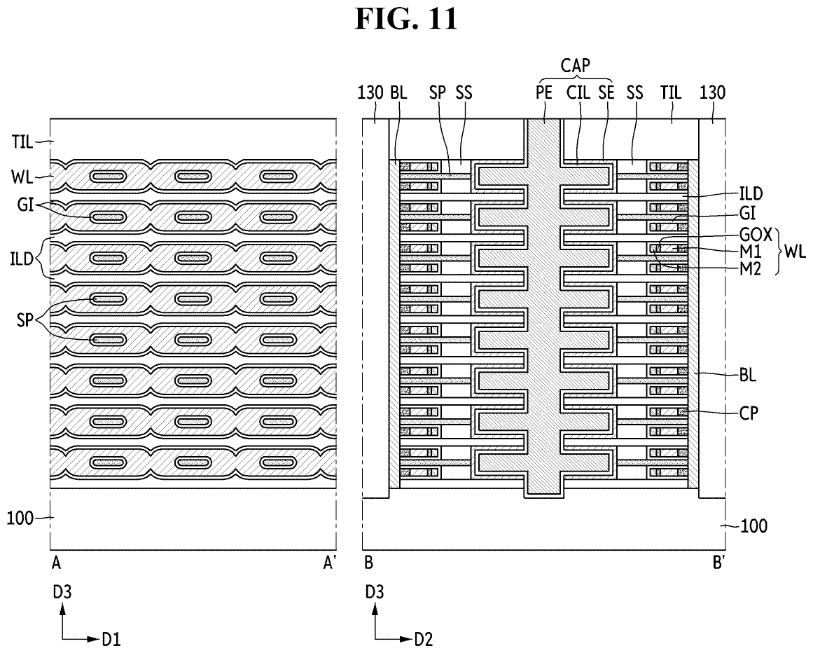

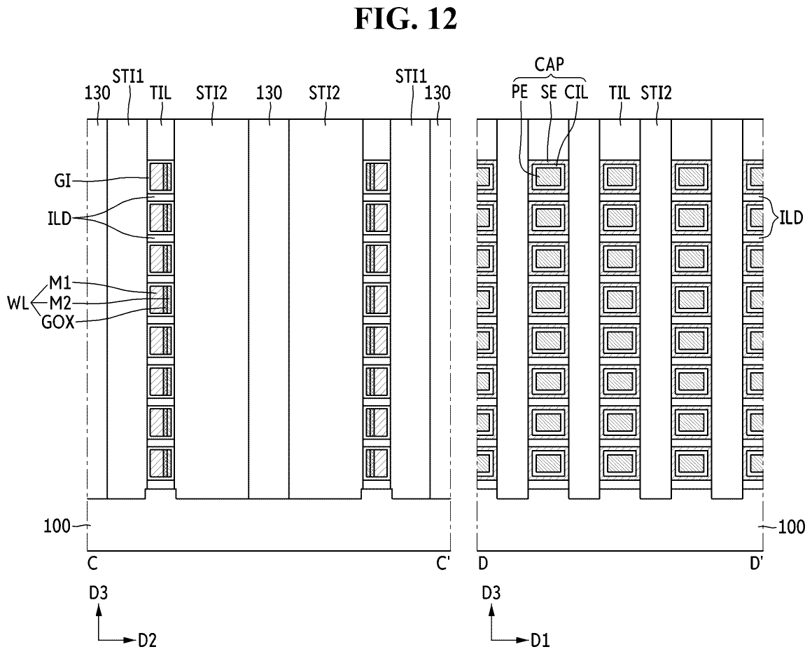

FIGS. 11 and 12 are views illustrating a semiconductor memory device according to some embodiments. For reference, FIG. 11 is a cross-sectional view taken along lines A-A′ and B-B′ of FIG. 3. FIG. 12 is a cross-sectional view taken along lines C-C′ and D-D′ of FIG. 3. FIG. 12 is a schematic view illustrating a shape of a grain of a cut surface taken along a second direction (e.g., the second direction D2) from the word line of FIGS. 10 and 11. For convenience of description, the description may be based on differences from that described with reference to FIGS. 1 to 9.

Referring to FIGS. 11 and 12, in the semiconductor memory device according to some embodiments, the word line WL may further include an oxide layer GOX between the first conductive pattern M1 and the second conductive pattern M2. The oxide layer GOX may be interposed between the first conductive pattern M1 and the second conductive pattern M2.

For example, the oxide layer GOX may include a metal oxide. For example, the oxide layer GOX may be a layer in which the second conductive pattern M2 is oxidized.

In some embodiments, the word line WL may further include a capping pattern CPP between the first conductive pattern M1 and the capping insulating pattern CP like FIGS. 8 to 10.

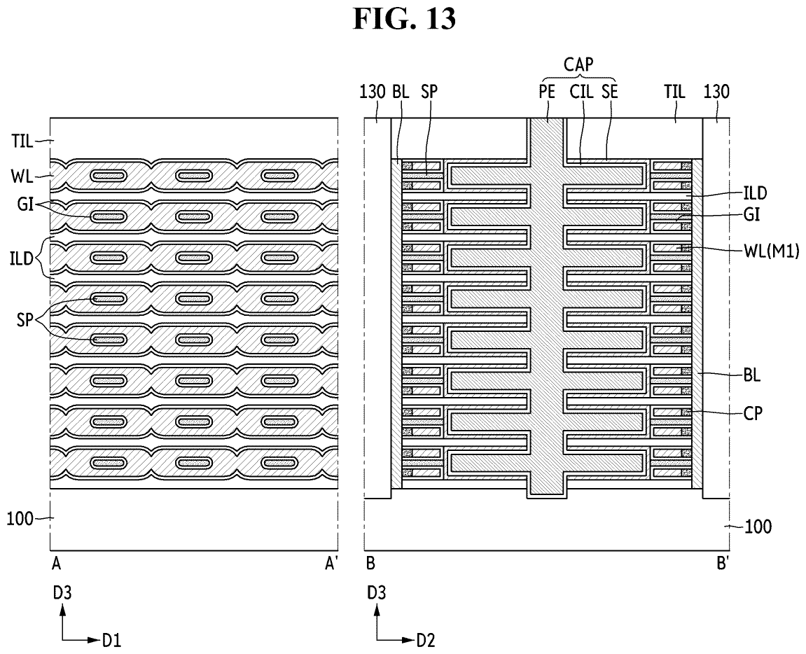

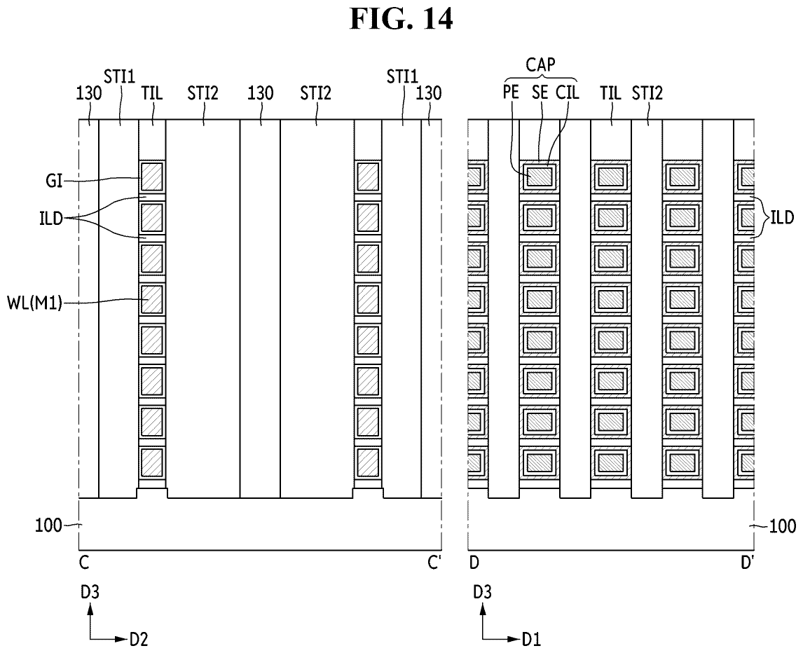

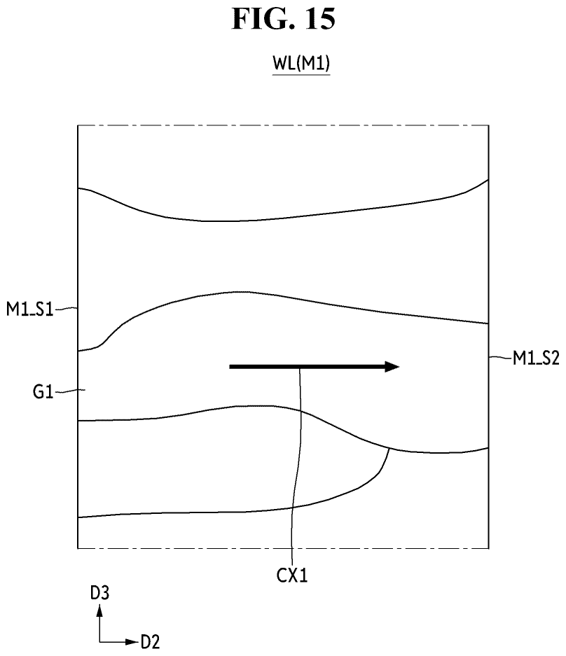

FIGS. 13 to 15 are views illustrating a semiconductor memory device according to some embodiments. For reference, FIG. 13 is a cross-sectional view taken along lines A-A′ and B-B′ of FIG. 3. FIG. 14 is a cross-sectional view taken along lines C-C′ and D-D′ of FIG. 3. FIG. 15 is a schematic view illustrating a shape of a grain of a cut surface taken along a second direction from a word line of FIGS. 10 and 11. For convenience of description, the description may be based on differences from that described with reference to FIGS. 1 to 12.

Referring to FIGS. 13 to 15, in the semiconductor memory device according to some embodiments, the word line WL may include only the first conductive pattern M1. A height of at least one of the plurality of first grains G1 in the second direction D2 may be the same as a height of the word line WL in the second direction D2.

The spacer insulating pattern (SS of FIGS. 1 to 12) may be omitted. The word line WL may be spaced apart from the capacitor CAP with the gate insulating layer GI interposed therebetween.

In some embodiments, the word line WL may further include a first conductive pattern M1 and a capping pattern (CPP of FIGS. 8 to 10) between the first conductive pattern M1 and the capping insulating pattern CP.

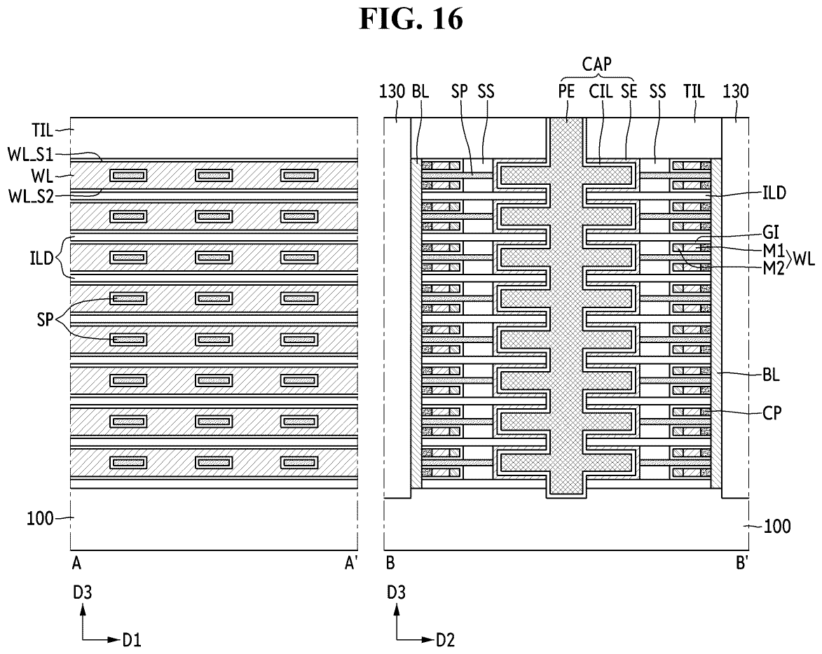

FIG. 16 is a view illustrating a semiconductor memory device according to some embodiments. For reference, FIG. 16 is a cross-sectional view taken along lines A-A′ and B-B′ of FIG. 3. For convenience of description, the description may be based on differences from that described with reference to FIGS. 1 to 15.

Referring to FIG. 16, in the semiconductor memory device according to some embodiments, the first surface WL_S1 and the second surface WL_S2 of the word line WL may be flat. That is, the first surface WL_S1 and the second surface WL_S2 may not include the recesses R1 and R2 of FIG. 2.

For example, the semiconductor pattern SP may have an angled edge. The word line WL may be extended along the periphery of the semiconductor pattern SP.

In some embodiments, the word line WL may include a first conductive pattern M1 and a second conductive pattern M2. In some embodiments, the word line WL may include a first conductive pattern M1, a second conductive pattern M2, and an oxide layer GOX between the first conductive pattern M1 and the second conductive pattern M2, as shown in FIGS. 11 and 12. In some embodiments, the word line WL may include only the first conductive pattern M1, as shown in FIGS. 13 and 14. In some embodiments, the word line WL may further include a capping pattern CPP between the first conductive pattern M1 and the capping insulating pattern CP as shown in FIGS. 8 to 10.

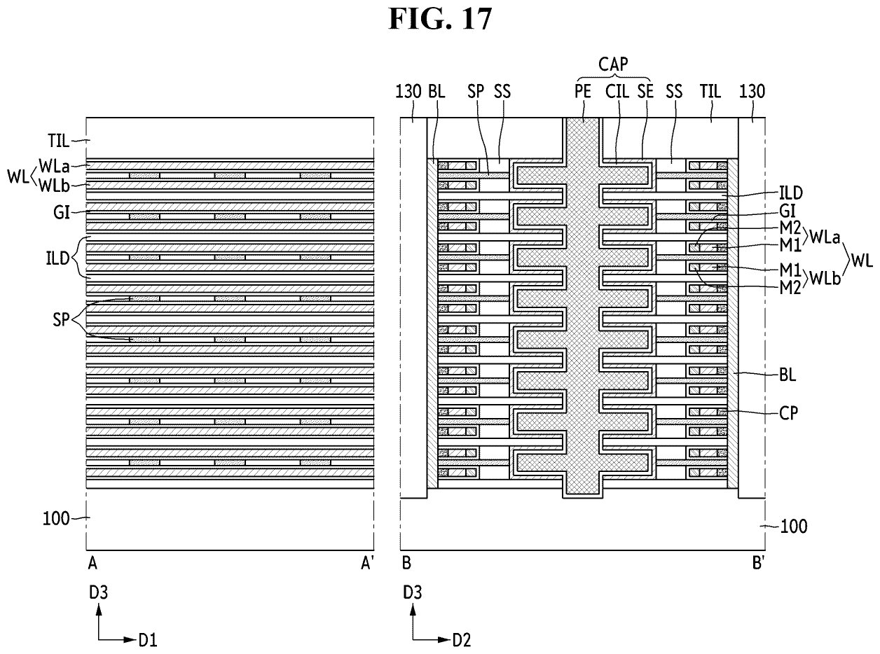

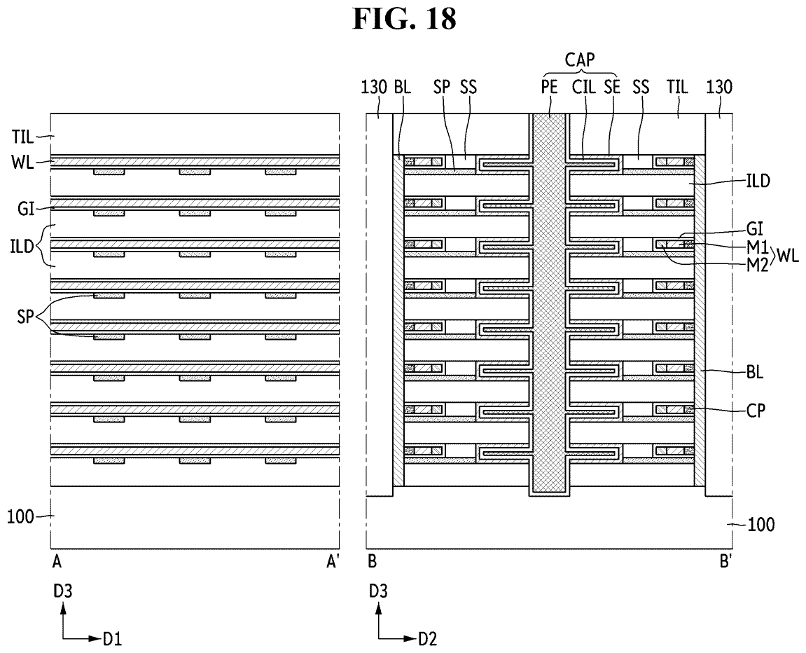

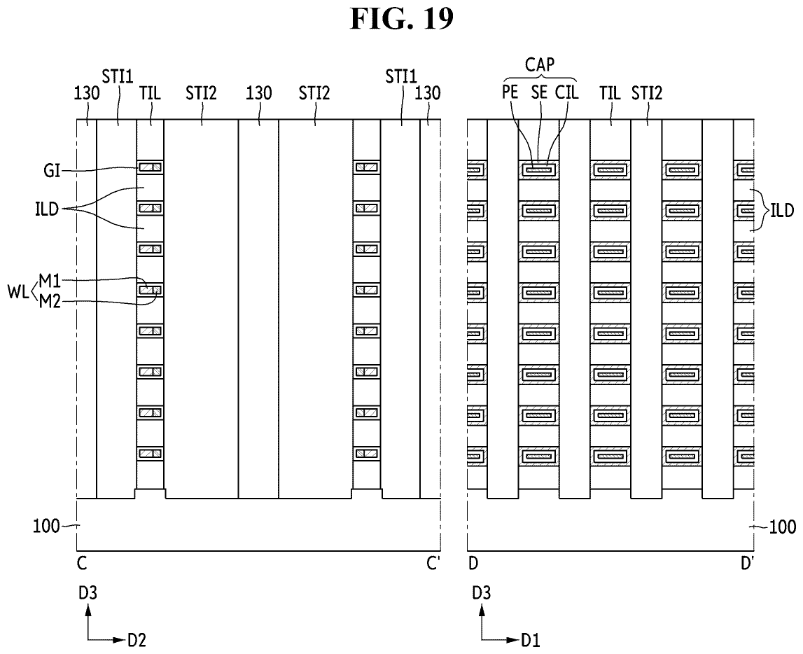

FIGS. 17 to 19 are views illustrating a semiconductor memory device according to some embodiments. For reference, FIGS. 17 and 18 are cross-sectional views taken along lines A-A′ and B-B′ of FIG. 3. FIG. 19 is a cross-sectional view taken along lines C-C′ and D-D′ of FIG. 3. For convenience of description, the description may be based on differences from that described with reference to FIGS. 1 to 16.

Referring to FIG. 17, in the semiconductor memory device according to some embodiments, a memory cell transistor may be a double gate transistor having word lines WL provided on both surfaces (e.g., opposite surfaces) of a channel region CH. The word line WL may include a first sub-word line WLa on the upper surface of the semiconductor pattern SP and a second sub-word line WLb on the lower surface of the semiconductor pattern SP. The first sub-word line WLa and the second sub-word line WLb may be spaced apart from each other in the third direction D3.

In some embodiments, the first sub-word line WLa and the second sub-word line WLb may include a first conductive pattern M1 and a second conductive pattern M2, respectively. In some embodiments, the first sub-word line WLa and the second sub-word line WLb may include a first conductive pattern M1, a second conductive pattern M2, and an oxide layer GOX between the first conductive pattern M1 and the second conductive pattern M2, respectively, as shown in FIGS. 11 and 12. In some embodiments, each of the first sub-word line WLa and the second sub-word line WLb may include only the first conductive pattern M1, as shown in FIGS. 13 and 14. In some embodiments, each of the first sub-word line WLa and the second sub-word line WLb may further include a capping pattern CPP between the first conductive pattern M1 and the capping insulating pattern CP as shown in FIGS. 8 to 10.

Referring to FIGS. 18 and 19, in the semiconductor memory device according to some embodiments, the memory cell transistor may be a transistor having a word line WL provided on one surface of the channel region CH. The word line WL may be disposed on the upper surface of the semiconductor pattern SP.

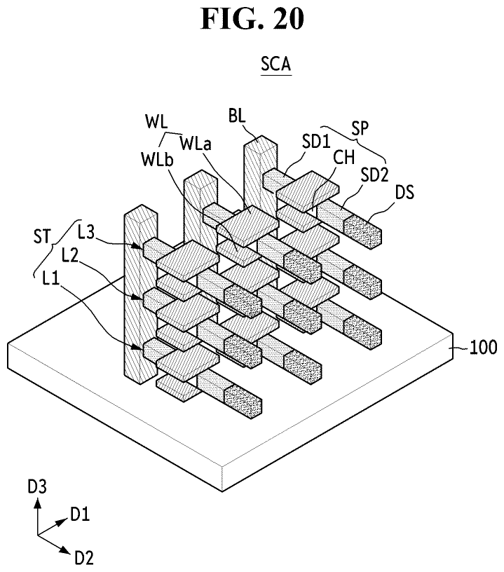

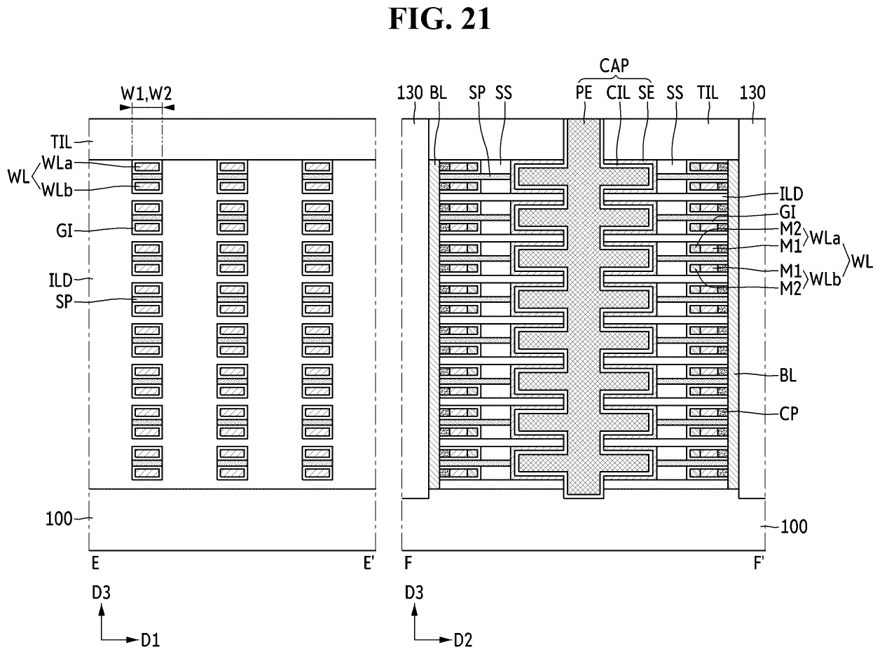

FIGS. 20 to 23 are views illustrating a semiconductor memory device according to some embodiments. For reference, E-E′ cross-sectional views of FIGS. 21 to 23 may be example cross-sectional views taken along the first direction D1 of the word line WL in FIG. 20, and F-F′ cross-sectional views of FIGS. 21 to 23 may be example cross-sectional views taken along the second direction D2 of the semiconductor pattern SP stacked in the third direction D3 in FIG. 20. For convenience of description, the description may be based on differences from that described with reference to FIGS. 1 to 19.

Referring to FIGS. 20 to 23, in the semiconductor memory device according to some embodiments, each word line WL may be disposed on each semiconductor pattern SP. Each word line WL may be disposed on the channel region CH of each of the semiconductor patterns SP, which are disposed to be spaced apart from each other in the first direction D1 at the same level.

For example, the plurality of semiconductor patterns SP of the first layer L1 may be arranged in the first direction D1, each bit line BL may be (electrically) connected to each semiconductor pattern SP of the first layer L1, and each word line WL of the first layer L1 may cross (or overlap in the third direction D3) the channel region CH of each semiconductor pattern SP of the first layer L1.

Referring to FIGS. 20 to 22, in some embodiments, the word line WL may include a first sub-word line WLa on the upper surface of the semiconductor pattern SP and a second sub-word line WLb on the lower surface of the semiconductor pattern SP. For example, the word line WL may be aligned with the channel region CH of the semiconductor pattern SP. The word line WL may overlap the channel region CH of the semiconductor pattern SP in the third direction D3.

Referring to FIG. 21, in some embodiments, a width W1 of the semiconductor pattern SP in the first direction D1 may be (substantially) the same as (equal to) a width W2 of the word line WL in the first direction D1.

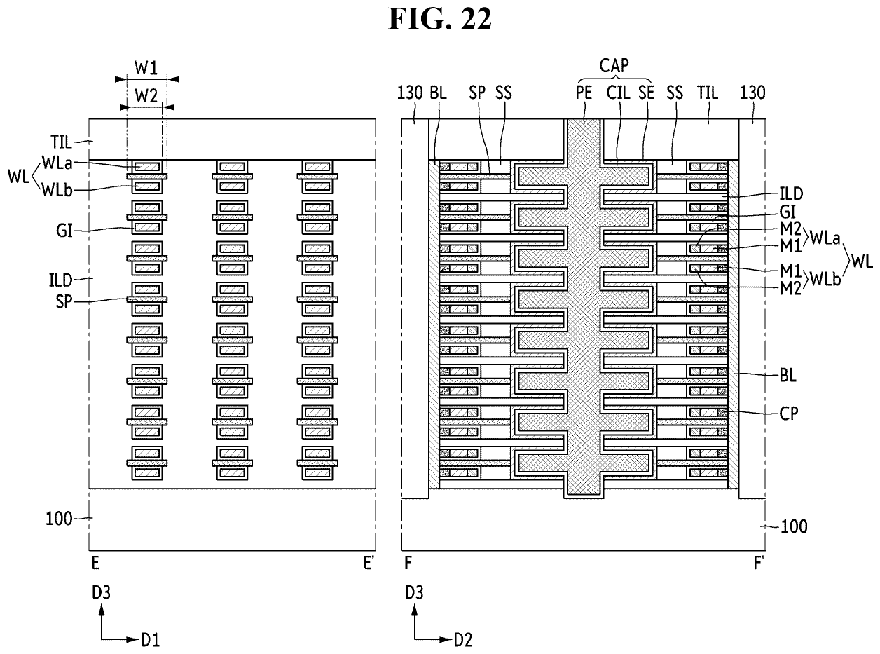

Referring to FIG. 22, in some embodiments, the width W1 of the semiconductor pattern SP in the first direction D1 may be different from the width W2 of the word line WL in the first direction D1. The width W1 of the semiconductor pattern SP in the first direction D1 may be greater than the width W2 of the word line WL in the first direction D1. The semiconductor pattern SP may be more protruded in the first direction D1 than both (opposite) sidewalls of the word line WL in the first direction D1.

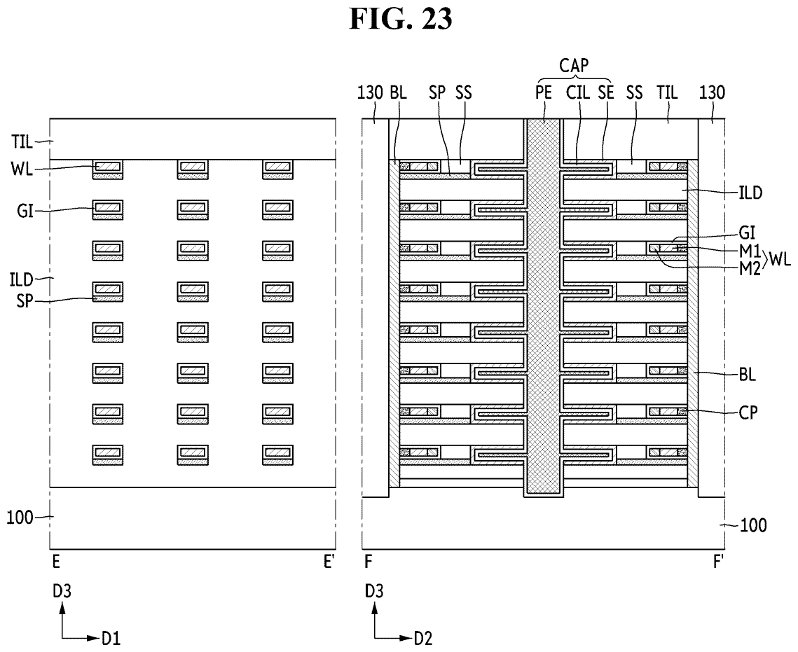

Referring to FIG. 23, in some embodiments, the memory cell transistor may be a transistor having a word line WL provided on one surface of the channel region CH. For example, the word line WL may be disposed on the upper surface of the semiconductor pattern SP.

The word line WL of FIGS. 20 to 23 may be any one of the word line WL described with reference to FIGS. 1 to 19.

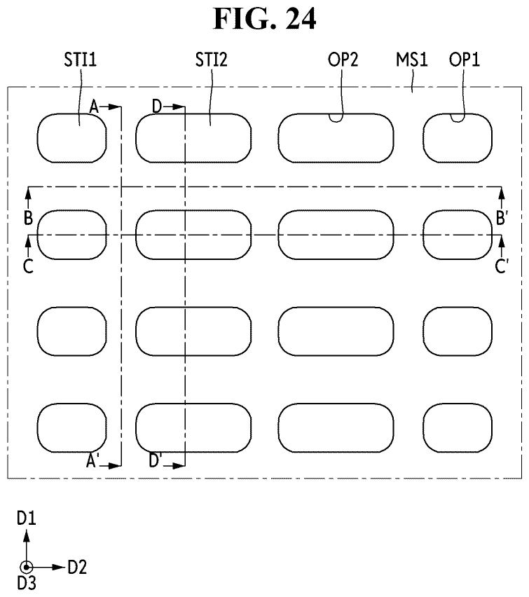

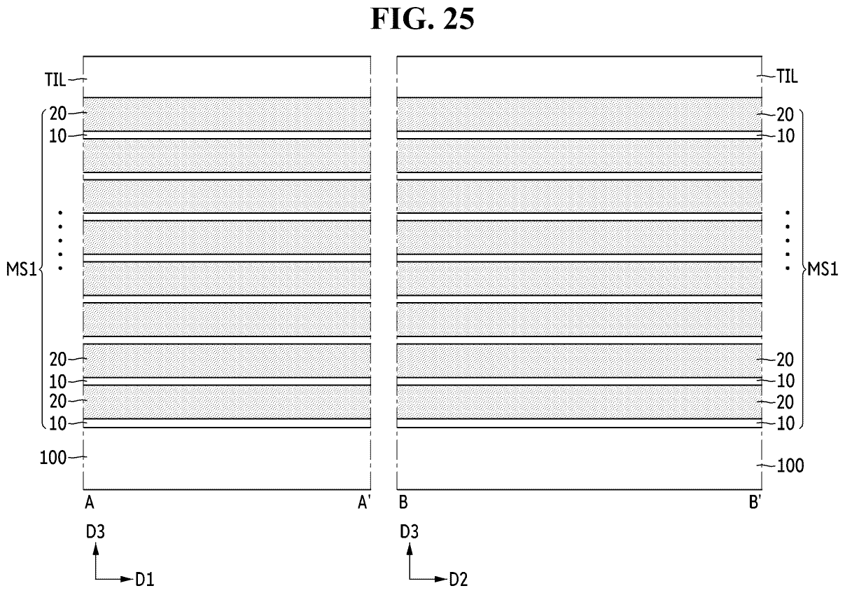

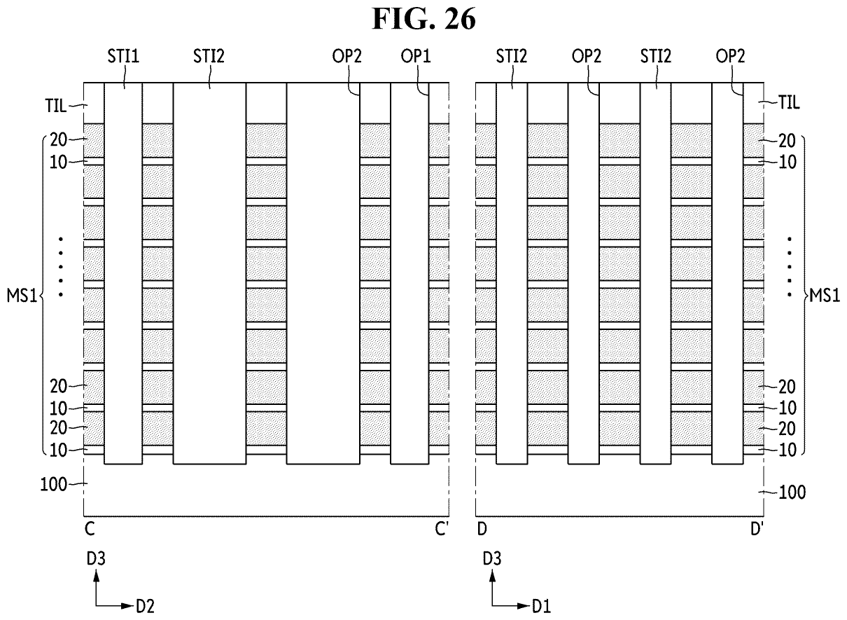

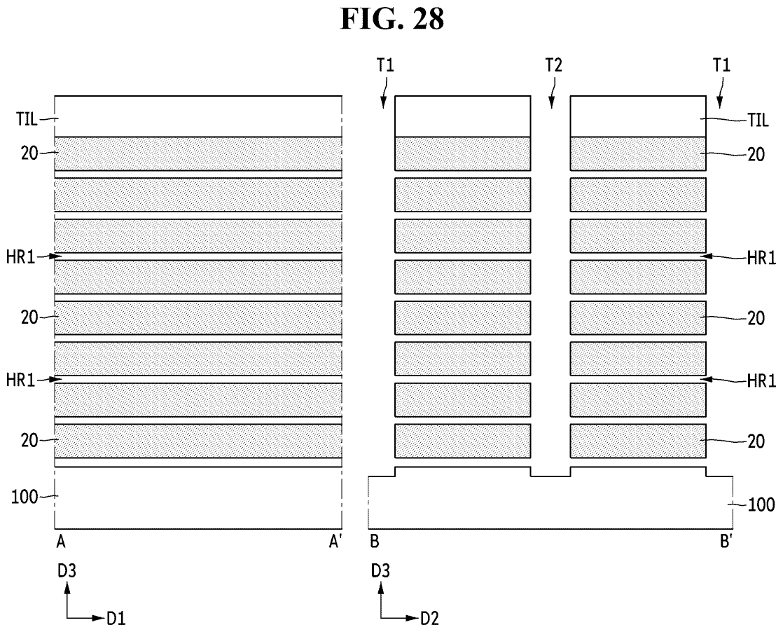

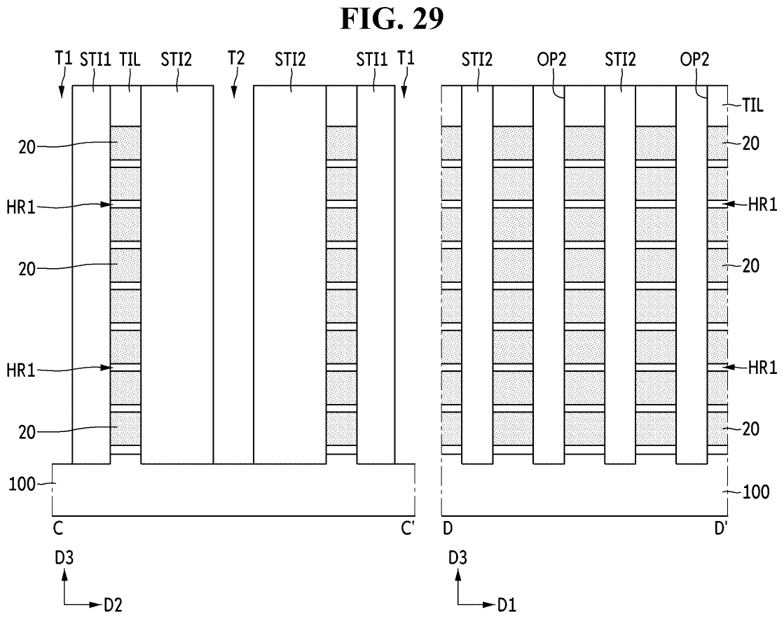

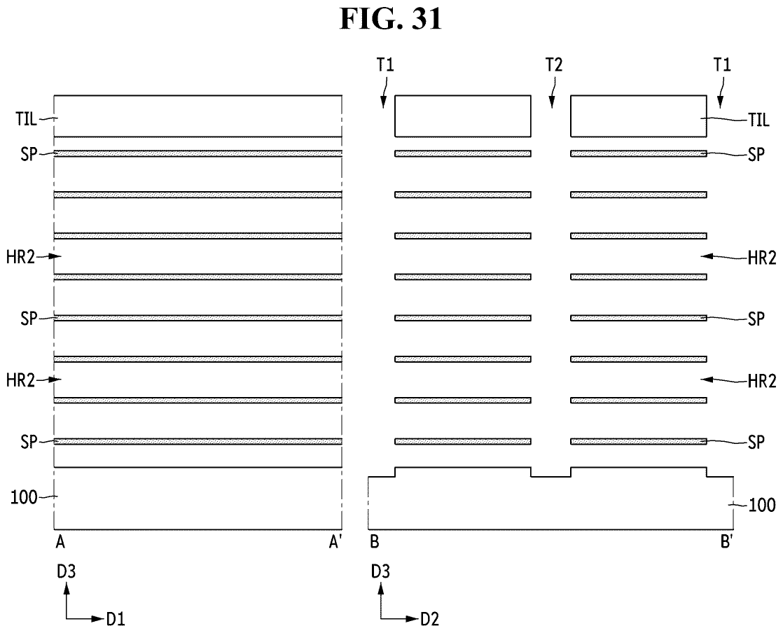

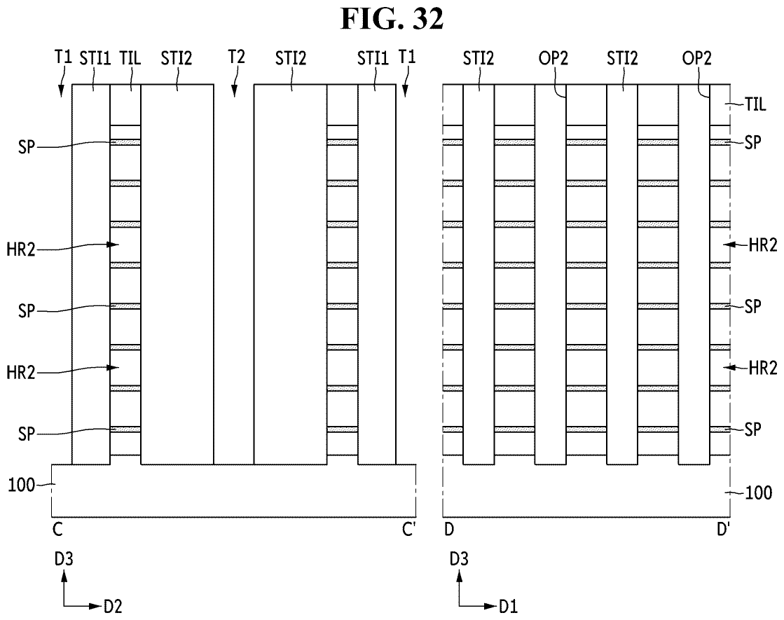

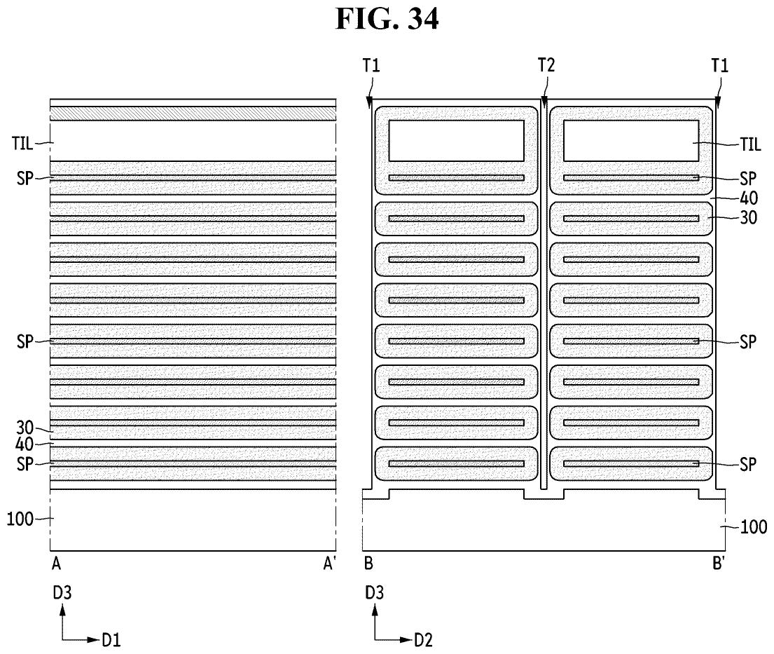

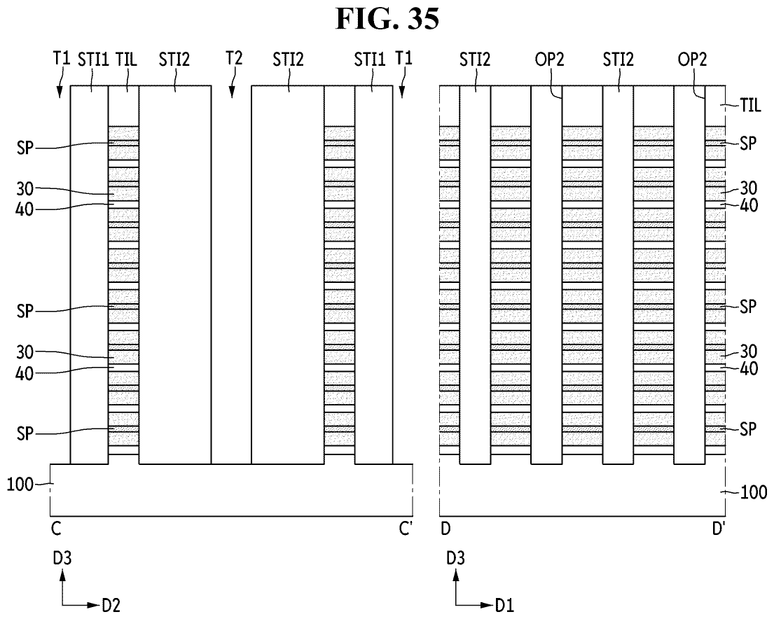

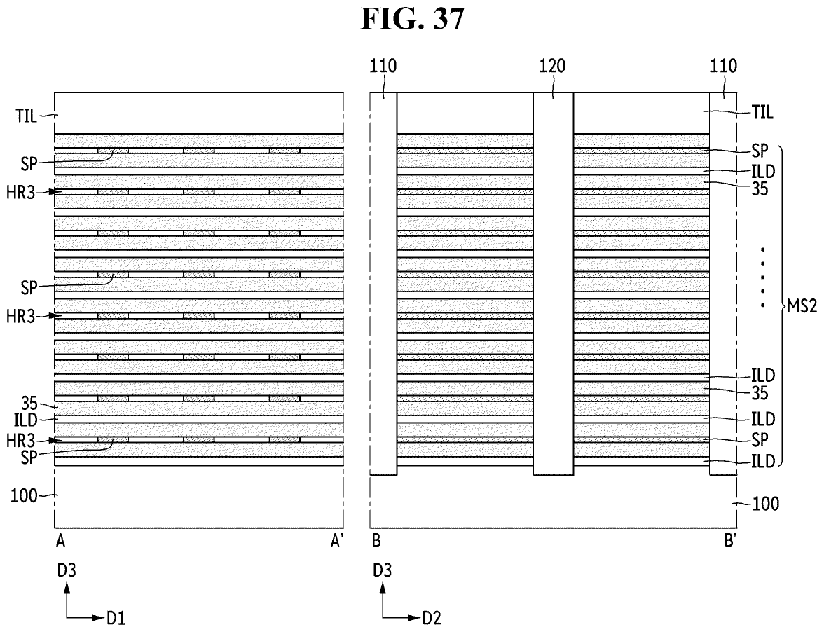

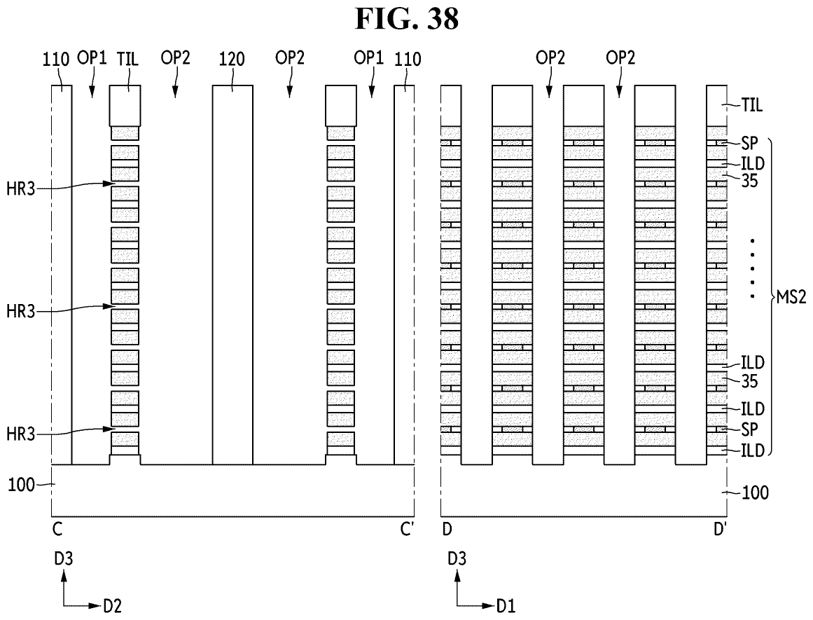

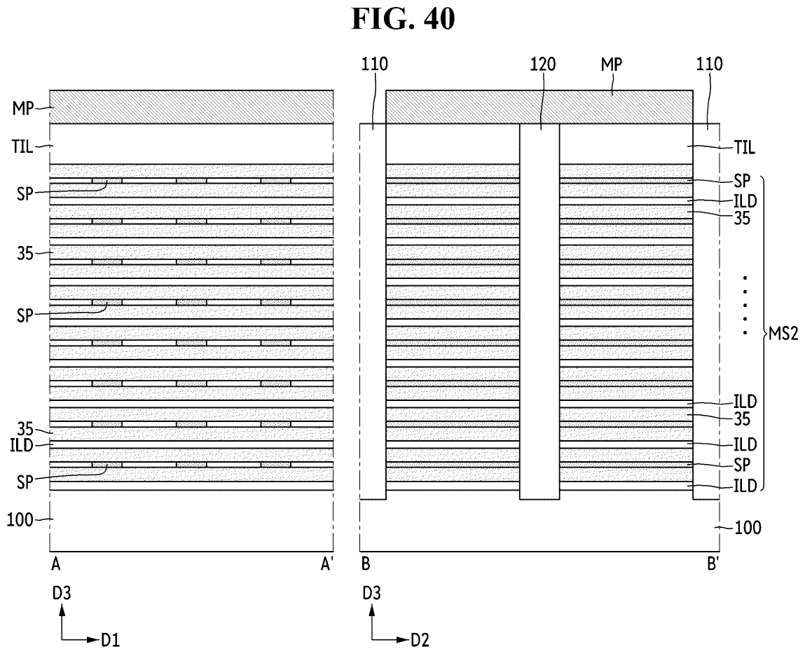

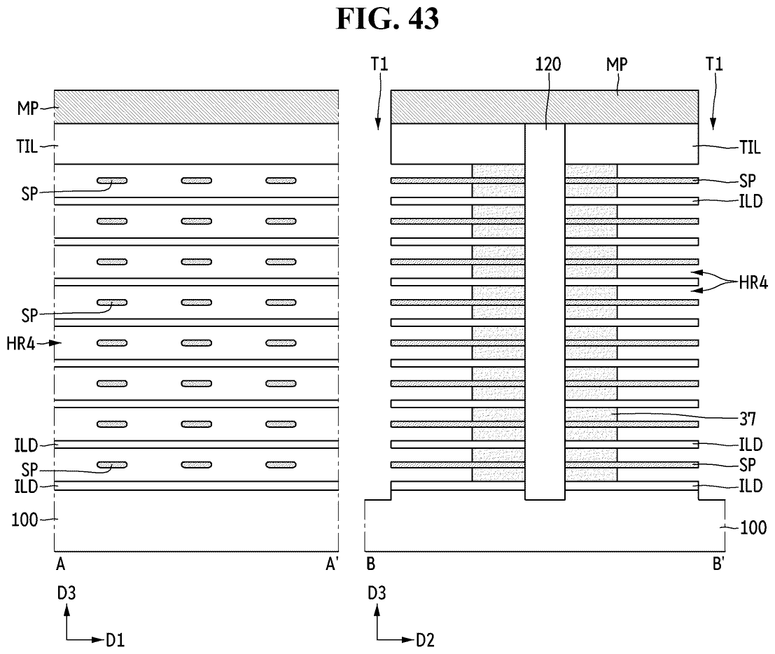

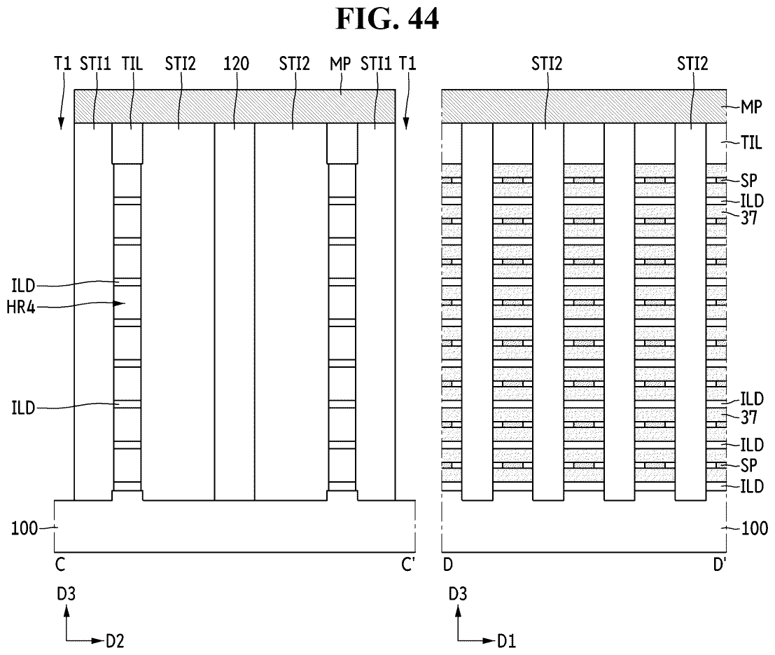

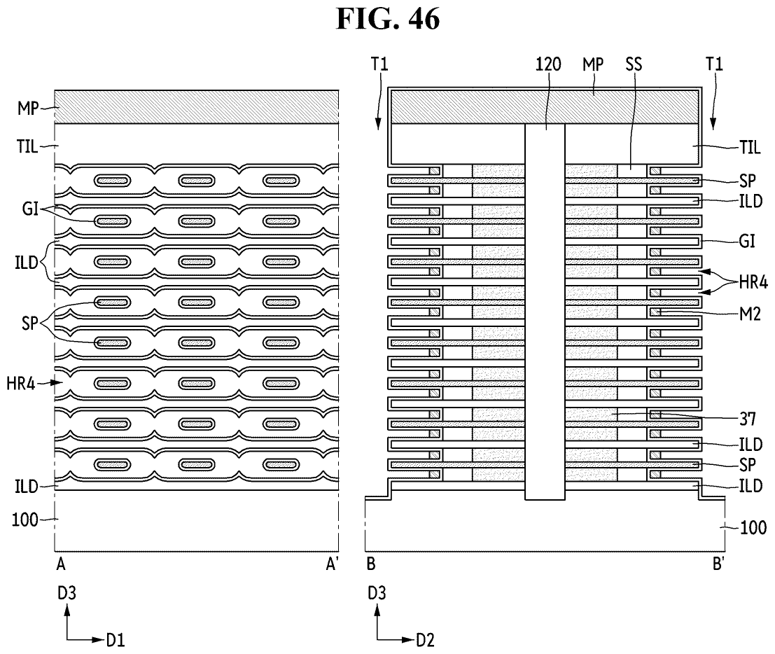

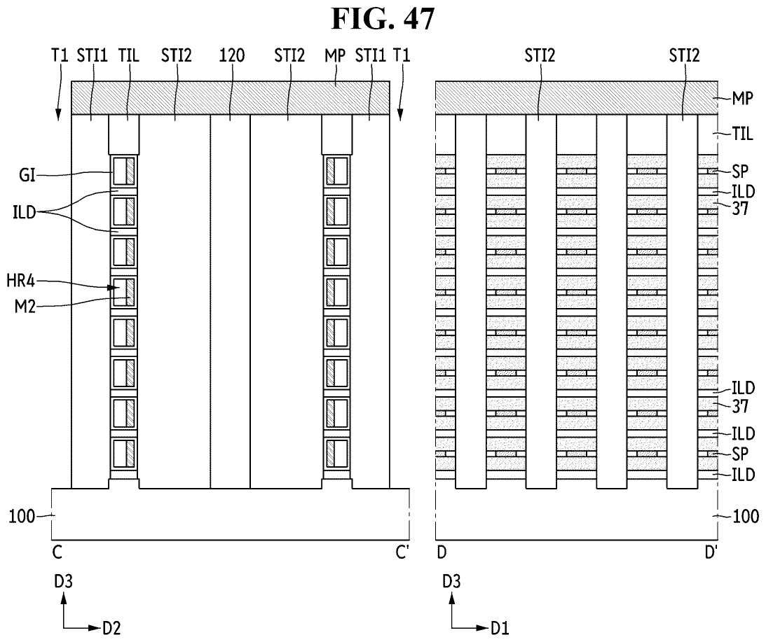

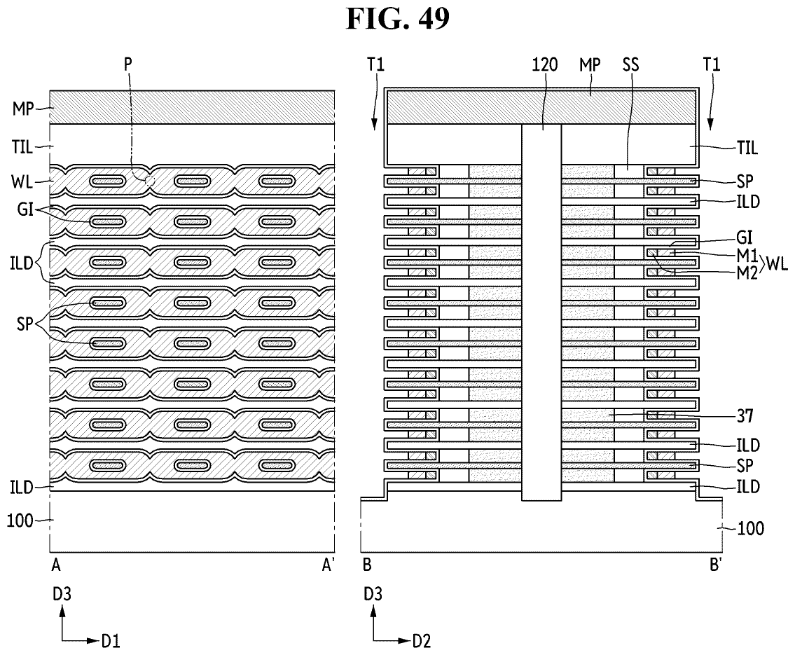

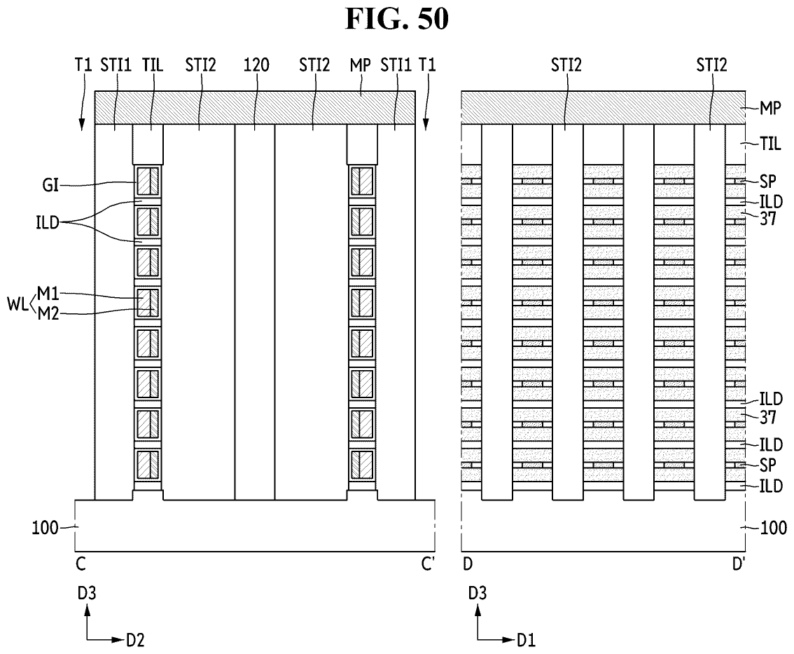

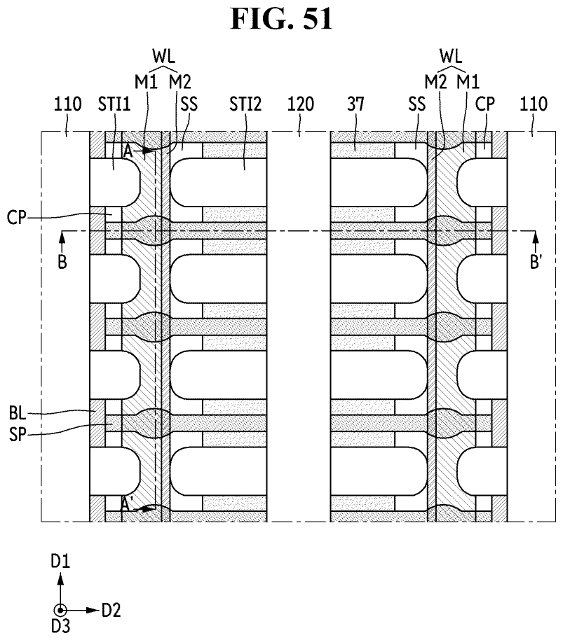

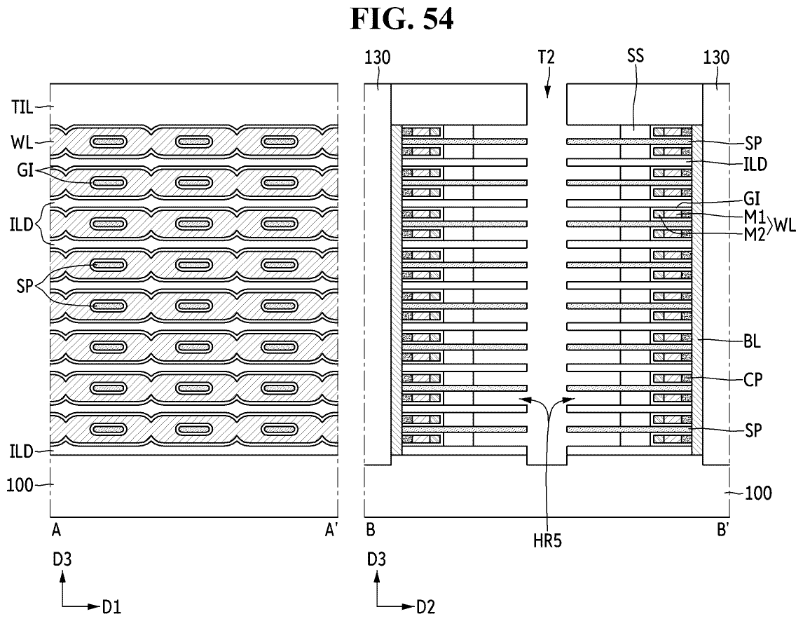

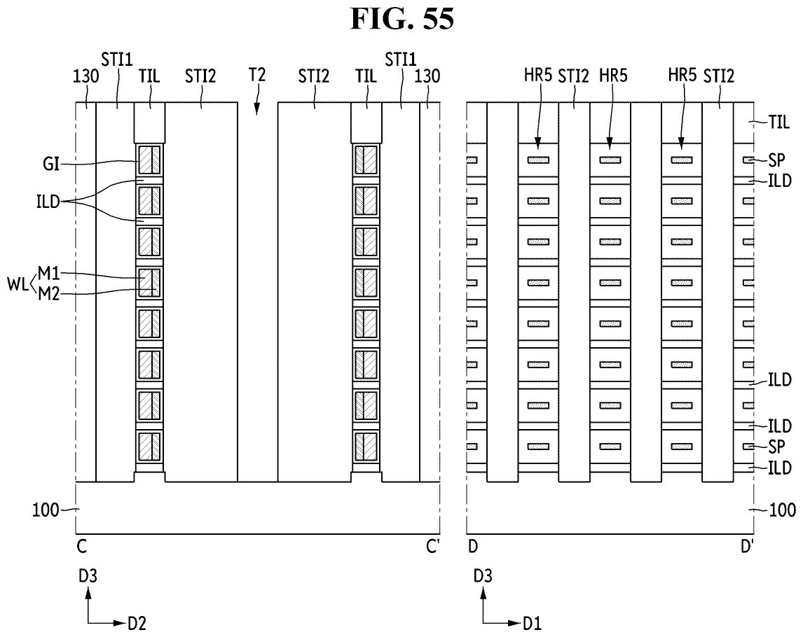

FIGS. 24 to 55 are views illustrating a method of fabricating a semiconductor memory device according to some embodiments. For convenience of description, the description may be based on differences from that described with reference to FIGS. 1 to 23.

Referring to FIGS. 24 to 26, a first mold structure MS1 including a first sacrificial layer 10 and a semiconductor layer 20, which are alternately stacked on the substrate 100, may be formed. A thickness of the first sacrificial layer 10 in the third direction D3 may be less (smaller) than that of the semiconductor layer 20 in the third direction D3.

The first sacrificial layer 10 may include (e.g., may be formed of) a material having etching selectivity with respect to the semiconductor layer 20. The first sacrificial layer 10 may include, for example, silicon germanium, a silicon oxide layer, a silicon nitride layer, and/or a silicon oxynitride layer. For example, the first sacrificial layer 10 may be a semiconductor material, for example, a silicon germanium layer. The semiconductor layer 20 may include, for example, silicon, germanium, silicon-germanium, and/or indium gallium zinc oxide (IGZO). The first sacrificial layer 10 and the semiconductor layer 20 may be formed by performing an epitaxial growth process.

An upper insulating layer TIL may be formed on the first mold structure MS1. The upper insulating layer TIL may be on (e.g., cover or overlap in the third direction D3) the uppermost semiconductor layer 20.

The upper insulating layer TIL may include (e.g., may be formed of) an insulating material having etching selectivity with respect to the first sacrificial layer 10 and the semiconductor layer 20. For example, the upper insulating layer TIL may be a silicon oxide layer.

Subsequently, first and second openings OP1 and OP2 for exposing the substrate 100 may be formed by patterning the upper insulating layer TIL and the first mold structure MS1.

Forming the first and second openings OP1 and OP2 may include forming a mask pattern, which has an opening corresponding to the first and second openings OP1 and OP2, on the first mold structure MS1, and (anisotropically) etching the first mold structure MS1 by using the mask pattern as an etching mask.

The first and second openings OP1 and OP2 may expose the upper surface of the substrate 100, and the upper surface of the substrate 100 below the first and second openings OP1 and OP2 may be recessed (toward a lower surface of the substrate 100) by over-etching during (anisotropic) etching.

The first openings OP1 may be formed to be spaced apart from each other along the first direction D1. The second openings OP2 may be formed to be spaced apart from each other along the first direction D1, and the second openings OP2 may be spaced apart from the first opening OP1 in the second direction D2. A pair of second openings OP2 may be formed between a pair of first openings OP1. The first openings OP1 may be spaced apart from each other at a first interval in the first direction D1. The second openings OP2 may be spaced apart from each other at the first interval in the first direction D1. In the second direction D2, the first opening OP1 may be spaced apart from the second opening OP2 at a second interval smaller than the first interval.

In the first direction D1, the first and second openings OP1 and OP2 may have the same width. In the second direction D2, the first opening OP1 may have a first length, and the second opening OP2 may have a second length greater than the first length.

Subsequently, the first and second separation insulating patterns STI1 and STI2 may be (at least partially) filled in the first and second openings OP1 and OP2, respectively.

The first and second separation insulating patterns STI1 and STI2 may be in contact with the substrate 100. The first and second separation insulating patterns STI1 and STI2 may be formed by depositing the separation insulating layer to (at least partially) fill the first and second openings OP1 and OP2 and then planarizing the separation insulating layer to expose an upper surface of the upper insulating layer TIL.

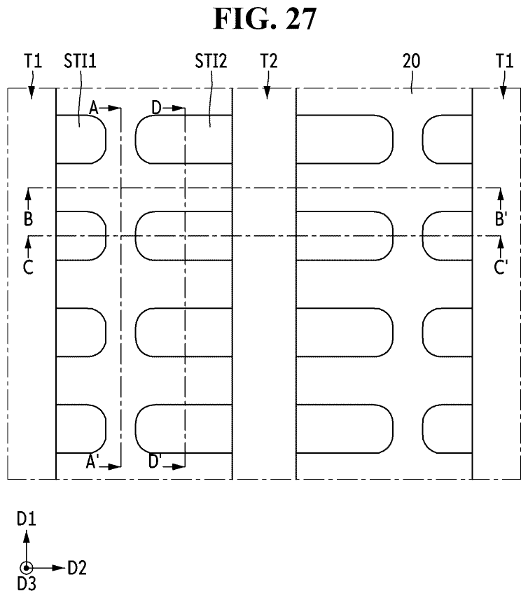

Referring to FIGS. 27 to 29, first and second trenches T1 and T2, which expose sidewalls of the first sacrificial layer 10 and the semiconductor layer 20 by extending in (e.g., passing through or penetrating) the first mold structure MS1, may be formed.

Forming the first and second trenches T1 and T2 may include forming a mask pattern having openings corresponding to the first and second trenches T1 and T2 on the first mold structure MS1 and (anisotropically) etching the first mold structure MS1 by using the mask pattern as an etching mask. The first and second trenches T1 and T2 may expose the upper surface of the substrate 100, and the upper surfaces of the substrate 100 below the first and second trenches T1 and T2 may be recessed (toward the lower surface of the substrate 100) by over-etching during (anisotropic) etching, whereby a recess region may be formed.

The first and second trenches T1 and T2 may be extended side by side along the first direction D1. The first and second trenches T1 and T2 may expose the sidewalls of the first sacrificial layer 10 and the semiconductor layer 20. Also, the first trench T1 may be extended along the first direction D1 to expose a sidewall of the first separation insulating pattern STI1. The second trench T2 may be formed between a pair of first trenches T1, and may be extended along the first direction D1 to expose a sidewall of the second separation insulating pattern STI2.

Subsequently, a first horizontal region HR1 may be formed between the semiconductor layers 20 adjacent to each other in the third direction D3 by removing the first sacrificial layer 10 exposed to the first and second trenches T1 and T2.

Forming the first horizontal region HR1 may include (isotropically) etching the first sacrificial layer 10 by performing an etching process having etching selectivity with respect to the substrate 100, the semiconductor layer 20, and the first and second separation insulating patterns STI1 and ST12. When the first sacrificial layer 10 is removed, the semiconductor layer 20 may not be collapsed by the first and second separation insulating patterns STI1 and ST12 but be vertically spaced apart therefrom (e.g., in the third direction D3).

A thickness of the first horizontal region HR1 in the third direction D3, that is, a distance between adjacent semiconductor layers 20 in the third direction D3 may be (substantially) the same as (equal to) a thickness of the first sacrificial layer 10 in the third direction D3.

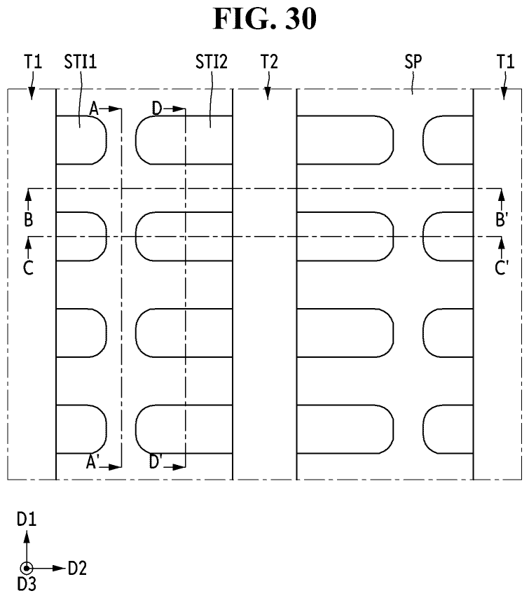

Referring to FIGS. 30 to 32, an enlargement process of increasing the thickness of the first horizontal region HR1 in the third direction D3 may be performed.

For example, the enlargement process may include etching the upper surface and the lower surface of the semiconductor layer 20 exposed to the first horizontal region HR1. The enlargement process may include performing an (isotropic) etching process having etching selectivity with respect to the upper insulating layer TIL and the first and second separation insulating patterns STI1 and SIT2. The thickness of each semiconductor layer 20 (in the third direction D3) may be reduced by the enlargement process. Therefore, the semiconductor pattern SP may be formed (by reducing the thickness of the semiconductor layer 20), and a second horizontal region HR2 may be formed between the semiconductor patterns SP adjacent to each other in the third direction D3 (by the enlargement process of the first horizontal region HR1).

According to the embodiment, an oxidation process for the semiconductor pattern SP may be performed, and thus, sacrificial oxide layers may be formed on the surface of the semiconductor pattern SP. Afterwards, the sacrificial oxide layers may be removed, and the surface of the semiconductor pattern SP may be exposed again. The distance between semiconductor patterns SP adjacent to each other in the third direction D3 may be increased by the removal of the sacrificial oxide layer. That is, the second horizontal region HR2 may be further extended (expanded) in the third direction D3. The thickness of the semiconductor pattern SP in the third direction D3 may be reduced by the oxidation process and the removal process.

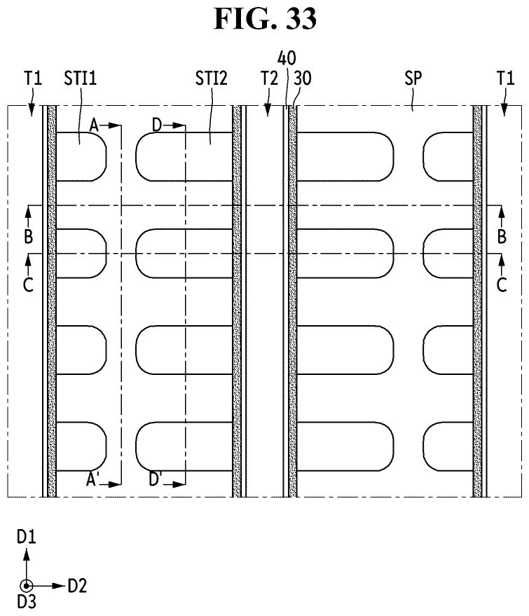

Referring to FIGS. 33 to 35, a second sacrificial layer 30 and an interlayer insulating layer 40 may be sequentially deposited on the surface of the semiconductor pattern SP.

The second sacrificial layer 30 may be formed by depositing a material having etching selectivity with respect to the substrate 100 and the semiconductor pattern SP. The second sacrificial layer 30 may include (e.g., may be formed of), for example, silicon oxide, silicon nitride, and/or silicon oxynitride. The second sacrificial layer 30 may be formed by, for example, an atomic layer deposition method and/or a chemical vapor deposition method.

The second sacrificial layer 30 may be formed to extend around (e.g., at least partially surround) each of the semiconductor patterns SP. The second sacrificial layer 30 may be formed to have a thickness less (smaller) than half of the thickness of each second horizontal region HR2 in the third direction D3. Therefore, after the second sacrificial layer 30 is deposited, a gap region may be defined between the semiconductor patterns SP adjacent to each other in the third direction D3.

Subsequently, the interlayer insulating layer 40 may be formed on the second sacrificial layer 30 to (at least partially) fill the second horizontal region HR2 in which the second sacrificial layer 30 is formed. The interlayer insulating layer 40 may include (e.g., may be formed of) an insulating material having etching selectivity with respect to the second sacrificial layer 30 and the substrate 100. For example, the interlayer insulating layer 40 may be formed of silicon oxide.

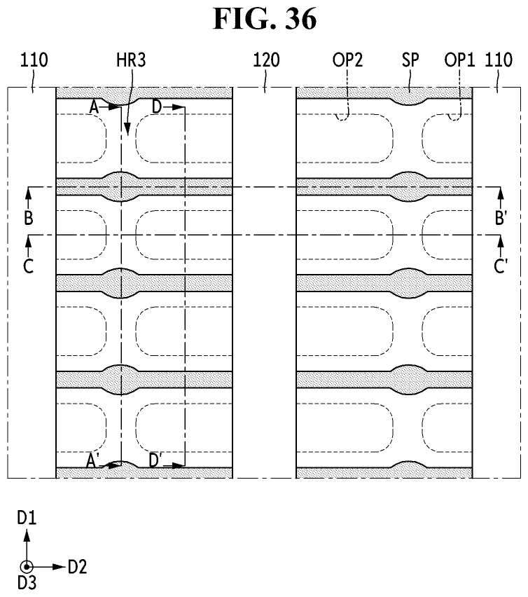

Referring to FIGS. 36 to 38, a second mold structure MS2 may be formed by sequentially performing a partial etching process for the interlayer insulating layer 40 and the second sacrificial layer 30.

In detail, after the interlayer insulating layer 40 is formed, a portion of the interlayer insulating layer 40 exposed to the first and second trenches T1 and T2 may be etched to form the interlayer insulating layer ILD. The interlayer insulating layer ILD may be formed by (isotropically) etching the interlayer insulating layer 40 until the second sacrificial layer 30 is exposed to the first and second trenches T1 and T2. The interlayer insulating layer ILD may have a rounded sidewall by the (isotropic) etching process. The interlayer insulating layers ILD may be separated from each other in the third direction D3.

Subsequently, after the interlayer insulating layer ILD is formed, a second sacrificial pattern 35 may be formed by etching a portion of the second sacrificial layer 30 exposed to the first and second trenches T1 and T2. The second sacrificial pattern 35 may be formed by (isotropically) etching the second sacrificial layer 30 until the semiconductor pattern SP is exposed. The second sacrificial pattern 35 may have a rounded sidewall by the (isotropic) etching process. The second sacrificial patterns 35 may be separated from each other in the third direction D3, and the semiconductor patterns SP may be disposed between a pair of second sacrificial patterns 35 adjacent to each other in the third direction D3, respectively.

Therefore, the second mold structure MS2 including an interlayer insulating layer ILD, a second sacrificial pattern 35 and a semiconductor pattern SP may be formed. Each of the second mold structures MS2 may include a plurality of stacked bodies that include a semiconductor pattern SP, a second sacrificial pattern 35, an interlayer insulating layer ILD and a second sacrificial pattern 35, which are sequentially stacked.

Subsequently, after the second mold structure MS2 is formed, first and second buried insulating patterns 110 and 120 for filling the first and second trenches T1 and T2, respectively may be formed.

Forming the first and second buried insulating patterns 110 and 120 may include forming a buried insulating layer for filling the first and second trenches T1 and T2 and planarizing the buried insulating layer to expose the upper surface of the upper insulating layer TIL. Planarizing the buried insulating layer may be performed by a planarization technique such as a chemical-mechanical polishing technique or an etch-back technique.

The first and second buried insulating patterns 110 and 120 may include (e.g., may be formed of) an insulating material having etching selectivity with respect to the first and second separation insulating patterns STI1 and STI2. For example, the first and second buried insulating patterns 110 and 120 may include (e.g., may be formed of) silicon oxide, silicon nitride, and/or silicon oxynitride. The first and second buried insulating patterns 110 and 120 may be formed of a single layer or multiple layers.

After the first and second buried insulating patterns 110 and 120 are formed, the first and second separation insulating patterns STI1 and STI2 may be removed so that the first and second openings OP1 and OP2 may be formed again. In this case, the first and second openings OP1 and OP2 may expose the sidewalls of the semiconductor pattern SP, the sidewalls of the second sacrificial pattern 35, the sidewalls of the interlayer insulating layer ILD and a portion of the upper surface of the substrate 100.

Removing the first and second separation insulating patterns STI1 and STI2 may include performing an etching process having etching selectivity with respect to the substrate 100, the second sacrificial pattern 35, the semiconductor pattern SP, and the first and second buried insulating patterns 110 and 120. For example, when the first and second separation insulating patterns STI1 and STI2 include silicon oxide, a dry etching process, a chemical etching process or a wet etching process may be performed for the first and second separation insulating patterns STI1 and STI2. For example, a buffered oxide etchant (BOE) and/or hydrogen fluoride (HF) may be used during a wet etching process for the first and second separation insulating patterns STI1 and STI2. CF4, NH3, CHF3, C2F6 and/or BF3 may be used during a dry etching process for the first and second separation insulating patterns STI1 and STI2.

An etching process may be performed for a portion of the semiconductor pattern SP exposed to the first and second openings OP1 and OP2. Therefore, the semiconductor patterns SP may be separated from each other in the first direction D1.

An (isotropic) etching process may be performed for the semiconductor pattern SP exposed to the first and second openings OP1 and OP2. That is, an etching etchant may be supplied through the first and second openings OP1 and OP2 so that the semiconductor pattern SP may be laterally etched along the first and second directions D1 and D2. In this case, since an interval between the first openings OP1 and an interval between the second openings OP2 are greater (larger) than an interval between the first and second openings OP1 and OP2, the semiconductor patterns SP separated from each other in the first direction D1 may be formed. As a result of the (isotropic) etching process, a width of each of the semiconductor patterns SP in the first direction D1 may be greater (larger) at a central portion than at a sidewall portion.

As the semiconductor pattern SP is formed as described above, a third horizontal region HR3 for exposing the sidewall of the semiconductor pattern SP may be formed between the second sacrificial patterns 35. The third horizontal region HR3 may correspond to a region in which the semiconductor pattern SP is etched.

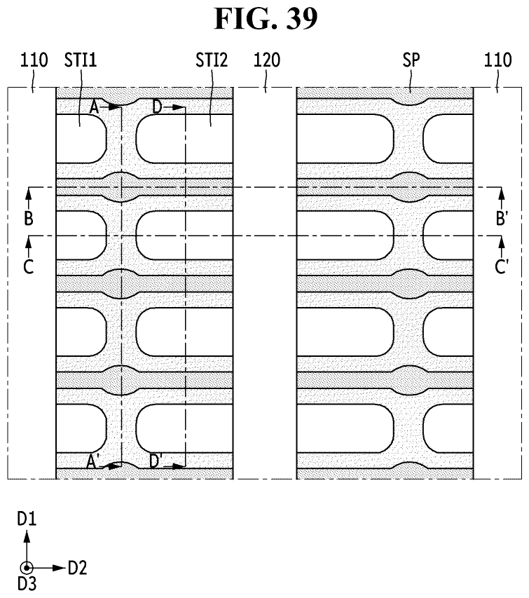

Referring to FIGS. 39 to 41, after the semiconductor pattern SP is formed, the insulating material may be filled in the first and second openings OP1 and OP2, so that the first and second separation insulating patterns STI1 and STI2 may be re-formed.

The first and second separation insulating patterns STI1 and STI2 may be formed of an insulating material having etching selectivity with respect to the second sacrificial pattern 35 and the interlayer insulating layer ILD. For example, the first and second separation insulating patterns STI1 and STI2 may include (e.g., may be formed of) silicon oxide, silicon oxynitride, and/or silicon nitride. The first and second separation insulating patterns STI1 and STI2 may be formed of a single layer or multiple layers.

Forming the first and second separation insulating patterns STI1 and STI2 may include forming an insulating layer for filling the first and second openings OP1 and OP2 and planarizing the insulating layer to expose the upper surface of the upper insulating layer TIL. Planarizing the insulating layer may be performed by a planarization technique such as a chemical-mechanical polishing technique or an etch-back technique. The insulating layer for filling the first and second openings OP1 and OP2 may be formed using, for example, an atomic layer deposition (ALD) process, a chemical vapor deposition (CVD) process, and/or a spin on glass (SOG) process.

While the first and second separation insulating patterns STI1 and STI2 are formed, the third horizontal region HR3 may be filled with an insulating material or may remain as an empty space.

After the first and second separation insulating patterns STI1 and STI2 are re-formed, a mask pattern MP for exposing the first buried insulating pattern 110 may be formed on the upper insulating layer TIL.

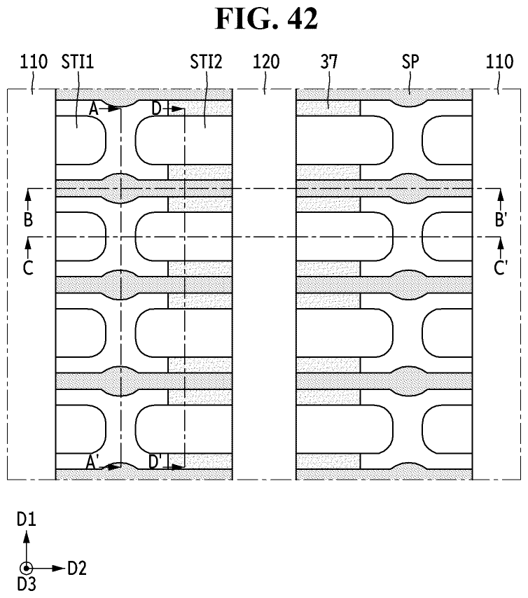

Referring to FIGS. 42 to 44, the first buried insulating pattern 110 may be etched using the mask pattern MP as an etching mask so that the first trench T1 for exposing the substrate 100 may be formed again. In this case, the first trench T1 may expose the sidewalls of the semiconductor pattern SP, the sidewalls of the second sacrificial pattern 35, and the sidewalls of the interlayer insulating layer ILD.

Subsequently, a fourth horizontal region HR4 may be formed between the semiconductor pattern SP and the interlayer insulating layer ILD by removing a portion of the second sacrificial pattern 35 exposed to the first trench T1.

The second sacrificial pattern 35 may be (isotropically) etched using an etching recipe having etching selectivity with respect to the semiconductor pattern SP and the interlayer insulating layer ILD, so that the fourth horizontal region HR4 may be formed. For example, when the second sacrificial pattern 35 is a silicon nitride layer and the interlayer insulating layer ILD is a silicon oxide layer, the fourth horizontal region HR4 may be formed by (isotropically) etching the second sacrificial pattern 35 using an etching solution containing phosphoric acid. The fourth horizontal region HR4 may be extended in the first direction D1 between the first and second separation insulating patterns STI1 and STI2.

As the fourth horizontal region HR4 is formed, a portion of the second sacrificial pattern 35 may remain so that a third sacrificial pattern 37 may be formed. The third sacrificial patterns 37 may be separated from each other in the first direction D1 by the second separation insulating pattern STI2.

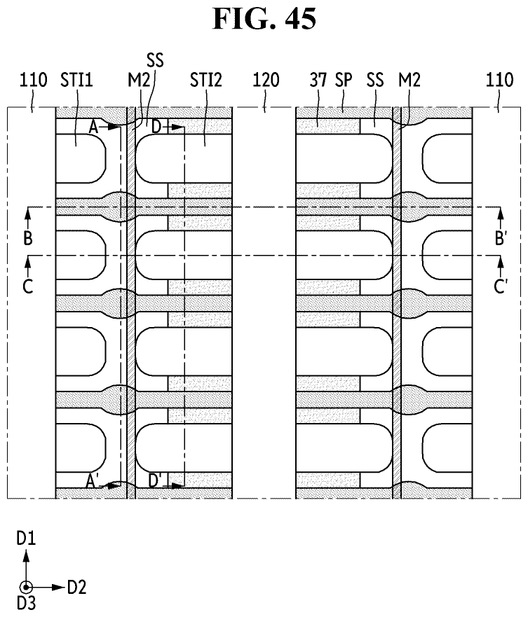

Referring to FIGS. 45 to 47, a spacer insulating pattern SS for filling a portion of the fourth horizontal region HR4 may be formed. Forming the spacer insulating pattern SS may include depositing an insulating layer to (at least partially) fill the fourth horizontal region HR4 and etching a portion of the insulating layer to remain a portion of the insulating layer. The spacer insulating patterns SS may be separated from each other in the first direction D1 by the second separation insulating pattern STI2.

A gate insulating layer GI may be formed on (to conformally cover) the fourth horizontal region HR4 and inner walls of the first trench T1. A second conductive pattern M2 for filling a portion of the fourth horizontal region HR4 may be formed on the gate insulating layer GI. The second conductive pattern M2 may be formed on the spacer insulating pattern SS.

Forming the second conductive pattern M2 may include forming a preliminary conductive pattern for (at least partially) filling the fourth horizontal region HR4 and the first trench T1 and forming a second conductive pattern M2 for (at least partially) filling a portion of the fourth horizontal region HR4 by etching a portion of the preliminary conductive pattern. Etching a portion of the preliminary conductive pattern may be performed by an etch-back technique.

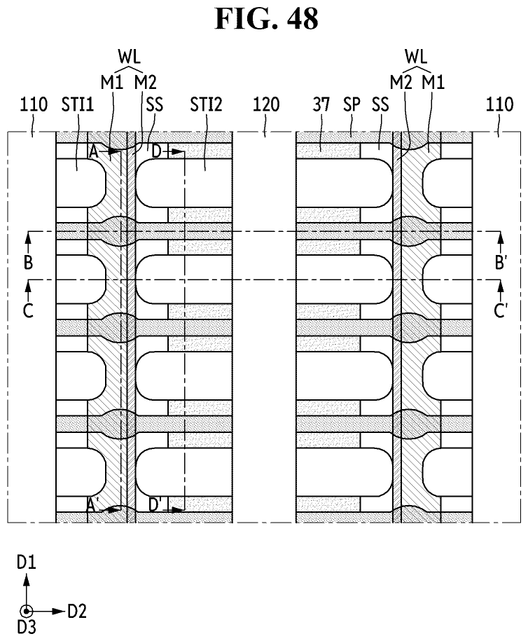

Referring to FIGS. 48 to 50, a first conductive pattern M1 for filling a portion of the fourth horizontal region HR4 may be formed on the gate insulating layer GI. The first conductive pattern M1 may be formed on the second conductive pattern M2. Therefore, the word line WL including the first conductive pattern M1 and the second conductive pattern M2 may be formed.

The first conductive pattern M1 may be grown on the second conductive pattern M2 in the second direction D2. The first conductive pattern M1 may be formed using a bottom-up growth method. The bottom-up growth method may include, for example, a selective growth method. The selective growth method may be, for example, a method of selectively depositing a conductive material on a conductive material. The second conductive pattern M2 may serve as a seed layer for selective growth of the first conductive pattern M1. Since the first conductive pattern M1 is formed by the bottom-up growth method, a crystal direction of the conductive material crystals contained in the first conductive pattern M1 may be the second direction D2. The bottom-up growth method is not limited to the gravitational direction or the opposite direction thereto. For example, a layer or a pattern formed by a bottom-up growth method may be grown in the first direction D1 and/or the second direction D2.

In some embodiments, an oxide layer may be further formed on the first conductive pattern M1. The second conductive pattern M2 may be formed on the oxide layer. In this case, as shown in FIGS. 11 and 12, the word line WL including the first conductive pattern M1, the oxide layer GOX, and the second conductive pattern M2 may be formed.

The word line WL may be formed by depositing a preliminary word line surrounding the semiconductor pattern SP and then etching a portion of the preliminary word line. When the preliminary word line is deposited, a quadruple point P between the semiconductor patterns SP adjacent to each other in the first direction D1 is likely to form a void due to weak filling. The quadruple point P may mean, for example, a point at which the preliminary word lines extended along the upper and lower surfaces of the semiconductor patterns SP adjacent to each other meet.

Also, in a process of etching a portion of the preliminary word line, an abnormal recess may be formed in the void of the preliminary word line. For example, a recess (a recess recessed toward the word line) may occur in a word line for filling a portion of the fourth horizontal region HR4. As a result, the word line WL may be disconnected and a defect such as GIDL may occur.

In the semiconductor memory device according to some embodiments, the word line WL may be formed by selective growth. The word line WL may be formed by being grown in a direction parallel with the semiconductor pattern SP, that is, in the second direction D2. Therefore, the word line WL may be formed at the quadruple point P without a void. As a result, the semiconductor memory device with improved performance may be provided.

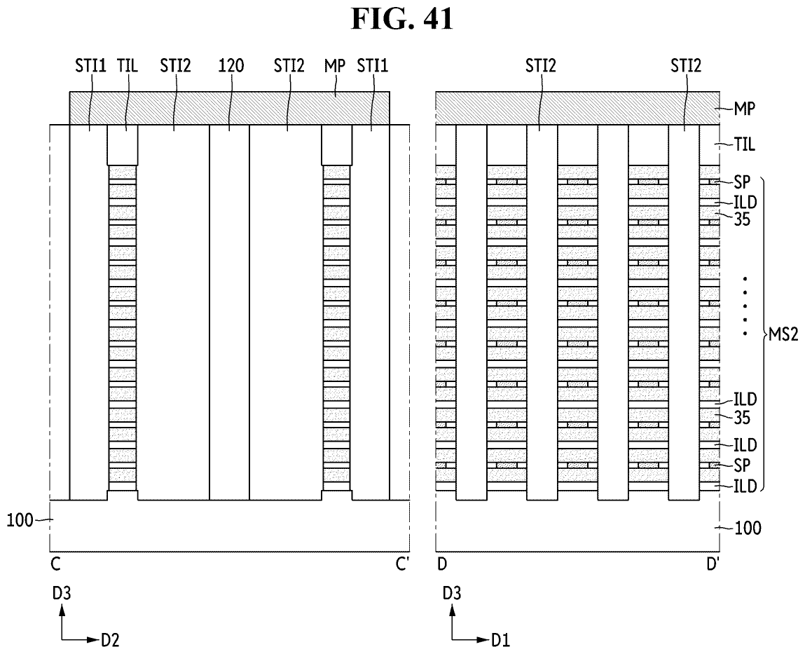

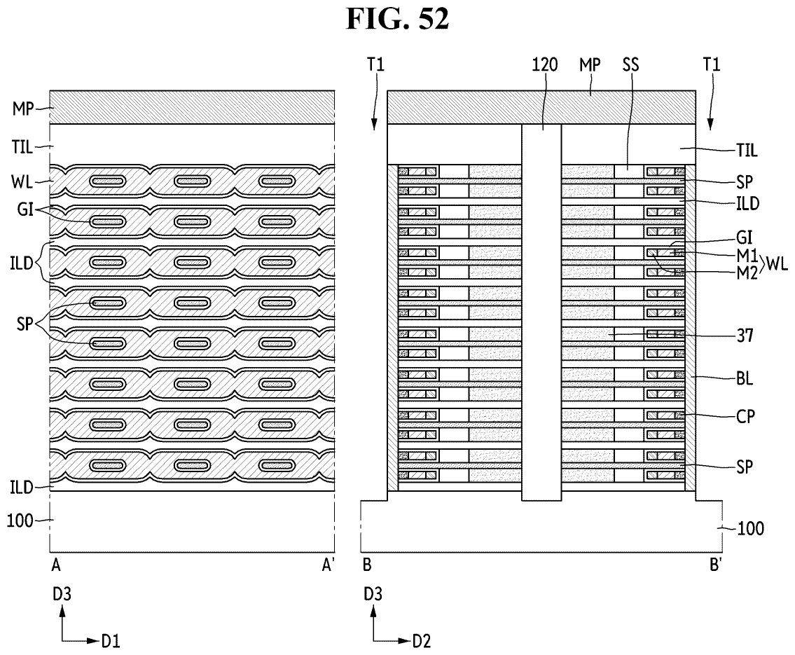

Referring to FIGS. 41 and 52, a capping insulating pattern CP for (at least partially) filling the fourth horizontal region HR4 in which the word line WL is formed may be formed.

Forming the capping insulating pattern CP may include forming a capping insulating layer on an inner wall of the first trench T1 to (at least partially) fill the fourth horizontal region HR4 and removing the capping insulating layer filled in the first trench T1 to expose the sidewall of the interlayer insulating layer ILD. The capping insulating layer may be etched by performing an (isotropic) etching process having etching selectivity with respect to the interlayer insulating layer ILD and the semiconductor pattern SP.

Before or after the capping insulating pattern CP is formed, a portion of the semiconductor pattern SP exposed by the first trench T1 may be doped with impurities. Therefore, a first impurity region may be formed in the semiconductor pattern SP. The first impurity region may be in contact with the bit line BL. The first impurity region may be formed by performing, for example, a vapor phase doping (GPD) process and/or a plasma doping (PLAD) process through the first trench T1.

After the capping insulating pattern CP is formed, the bit line BL may be formed in the first trench T1.

Forming the bit line BL may include depositing a conductive layer on the inner wall of the first trench T1 to (at least partially) fill a space between the first separation insulating patterns STI1 and then removing the conductive layer so that the sidewall of the first separation insulating pattern STI1 is exposed on the inner wall of the first trench T1. After the bit line BL is formed, the mask pattern MP may be removed.

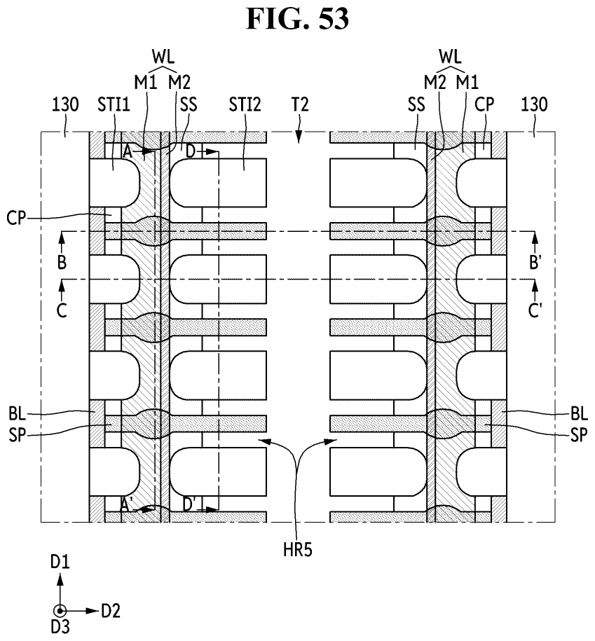

Referring to FIGS. 53 to 55, after the bit line BL is formed, the buried insulating pattern 130 may be formed in the first trench T1. The buried insulating pattern 130 may be extended along the first direction D1 on the substrate 100.

Subsequently, the second trench T2 may be re-formed by removing the second buried insulating pattern 120. In this case, the upper surface of the substrate 100, the sidewall of the third sacrificial pattern 37, the sidewall of the semiconductor pattern SP, and the sidewall of the interlayer insulating layer ILD may be exposed to the second trench T2.

Subsequently, a fifth horizontal region HR5 for exposing the spacer insulating pattern SS may be formed by removing the third sacrificial pattern 37 exposed to the second trench T2.

Forming the fifth horizontal region HR5 may include (isotropically) etching the third sacrificial pattern 37 by performing an etching process having etching selectivity with respect to the substrate 100, the semiconductor pattern SP, and the interlayer insulating layer ILD. When the third sacrificial pattern 37 is (isotropically) etched, the spacer insulating pattern SS may be used as an etching stop layer. The fifth horizontal region HR5 may be formed between the interlayer insulating layer ILD and the semiconductor pattern SP in the vertical direction (e.g., I the third direction D3) and between the second separation insulating patterns STI2 in the horizontal direction (e.g., in the first direction D1 and/or the second direction D2).

In some embodiments, forming the fifth horizontal region HR5 may further include removing the spacer insulating pattern SS and the second conductive pattern M2. In this case, the word line WL including the first conductive pattern M1 may be formed as shown in FIGS. 13 and 14. When the oxide layer GOX is formed on the first conductive pattern M1, the oxide layer GOX may be also removed in the process of removing the spacer insulating pattern SS and the second conductive pattern M2.

Subsequently, a portion of the semiconductor pattern SP exposed to the fifth horizontal region HR5 may be etched to reduce a length of the semiconductor pattern SP in the second direction D2. That is, after the fifth horizontal region HR5 is formed, a portion of the semiconductor pattern SP may be (isotropically) etched.

Referring to FIGS. 3 to 6, a second impurity region SD2 may be formed by doping impurities on a portion of the semiconductor pattern SP.

Subsequently, the storage electrode SE may be locally formed in the fifth horizontal region HR5. The storage electrode SE may be in contact with the second impurity region SD2.

Forming the storage electrode SE may include depositing a conductive layer on (e.g., conformally covering) the inner wall of the fifth horizontal region HR5 and the inner wall of the second trench T2 and removing a portion of the conductive layer deposited on the inner wall of the second trench T2 to locally remain in the fifth horizontal region HR5.

The storage electrodes SE may be spaced apart from each other in the first direction D1, the second direction D2, and the third direction D3. The storage electrode SE may be in contact with the semiconductor pattern SP exposed by the fifth horizontal region HR5. Each of the storage electrodes SE may define an empty space in the fifth horizontal region HR5. Each of the storage electrodes SE may have a long axis in the second direction D2, and may have a hollow cylinder shape. In contrast, the storage electrode SE may have a pillar shape having a long axis in the second direction D2.

Subsequently, a capacitor dielectric layer CIL may be formed on (to conformally cover) the fifth horizontal region HR5 in which the storage electrode SE is formed, and a plate electrode PE for (at least partially) filling the fifth horizontal region HR5, in which the storage electrode SE and the capacitor dielectric layer CIL are formed, and the second trench T2 may be formed.

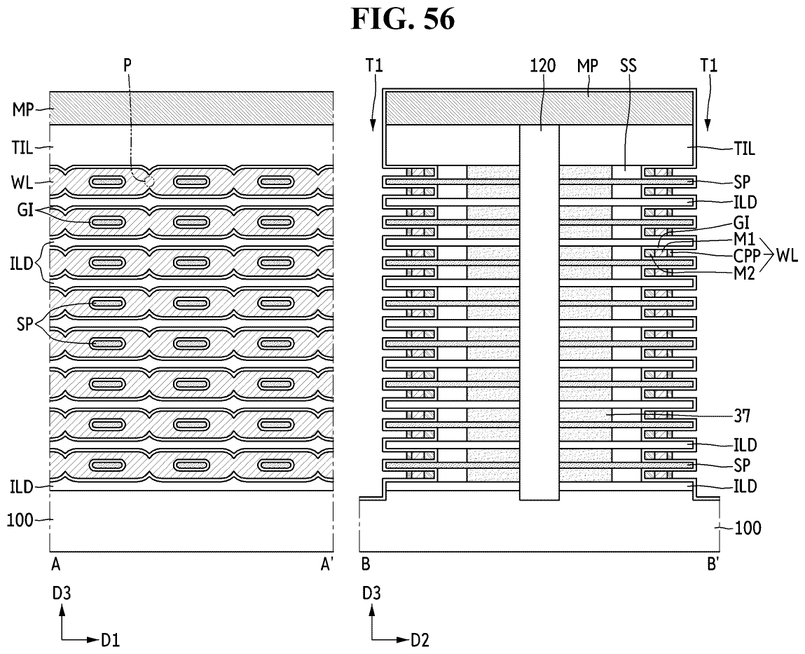

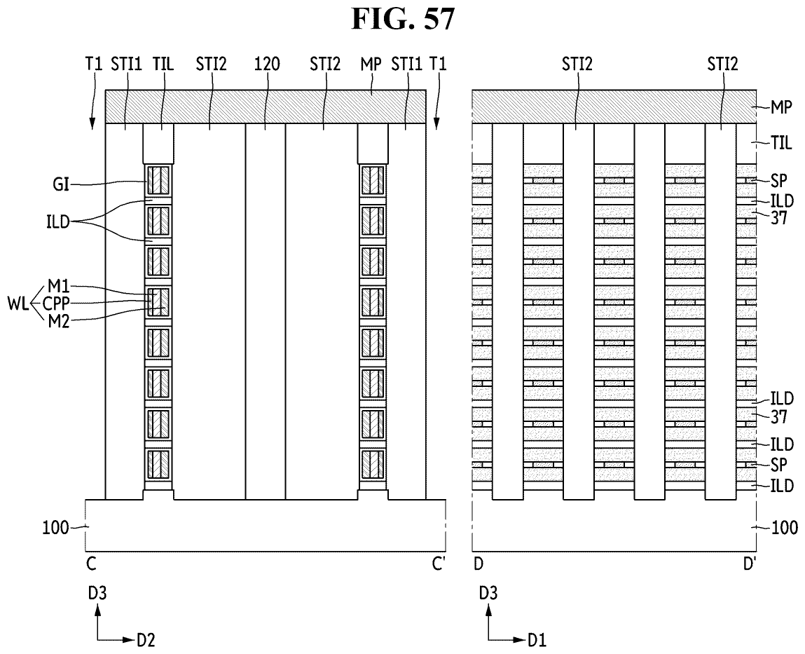

FIGS. 56 and 57 are views illustrating a method of fabricating a semiconductor memory device according to some embodiments. For convenience of description, the description will be described based on differences from that described with reference to FIGS. 1 to 55. For reference, FIGS. 56 and 57 are views subsequent to FIGS. 48 to 50.

Referring to FIGS. 56 and 57, a capping pattern CPP for filling a portion of the fourth horizontal region HR4 may be formed on the first conductive pattern M1. The capping pattern CPP may be formed on the first conductive pattern M1. Accordingly, the word line WL including the first conductive pattern M1, the second conductive pattern M2, and the capping pattern CPP may be formed. When the capping insulating pattern CP is formed later, the word line WL, that is, the first conductive pattern M1 may be prevented from being oxidized by the capping pattern CPP. The first conductive pattern M1 may be protected by the capping pattern CPP.

In some embodiments, forming the capping pattern CPP may include performing a soaking process for the first conductive pattern M1. The soaking process may include supplying SiH₄ gas, SiH₄ and NH₃ gas, or SiH₄ and N₂ gas to the first conductive pattern M1. Accordingly, the capping pattern CPP may be formed on the first conductive pattern M1. The capping pattern CPP may be a portion of the first conductive pattern M1. In this case, a boundary between the capping pattern CPP and the first conductive pattern M1 may not be distinguished.

In some embodiments, forming the capping pattern CPP may include forming a preliminary capping layer for filling the fourth horizontal region HR4 and the first trench T1, and forming a capping pattern CPP for filling a portion of the fourth horizontal region HR4 by etching a portion of the preliminary capping layer. The etching of a portion of the preliminary capping layer may be performed by an etch-back technique. In this case, the boundary between the capping pattern CPP and the first conductive pattern M1 may be distinguished. A shape of the grain of the capping pattern CPP may be different from a shape of the grain of the first conductive pattern M1.

Subsequently, the fabricating process of FIGS. 41 to 55 may be performed. Accordingly, the semiconductor memory device of FIGS. 8 to 10 may be fabricated.

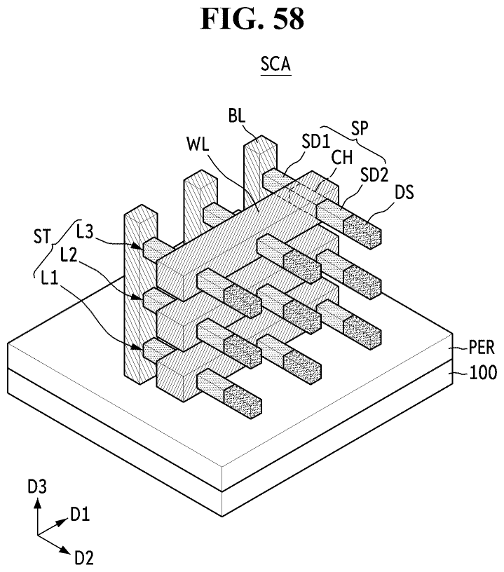

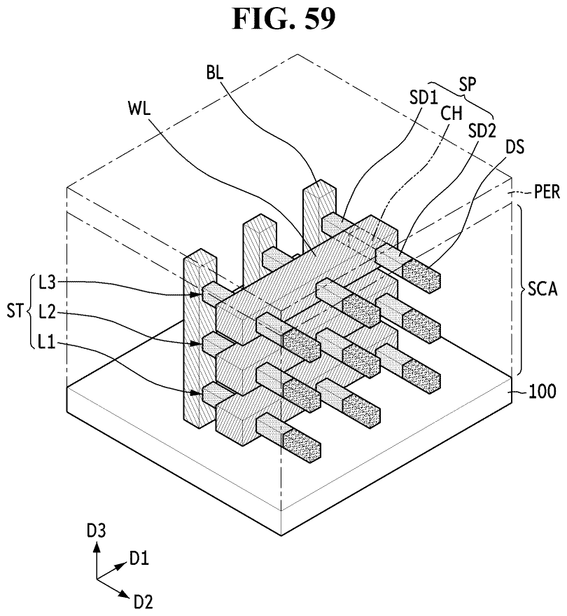

FIGS. 58 and 59 are example perspective views illustrating a semiconductor memory device according to some embodiments.

Referring to FIGS. 58 and 59, a peripheral circuit region PER and a sub-cell array SCA may be stacked in the third direction D3.

In FIG. 58, the peripheral circuit region PER may be disposed between the substrate 100 and a plurality of sub-cell arrays SCA. The sub-cell array SCA may be disposed on the peripheral circuit region PER.

The peripheral circuit region PER may include peripheral circuit transistors formed on the substrate 100. The peripheral circuit region PER may include a circuit for operating the semiconductor memory device according to some embodiments.

A wiring layer electrically connected to the sub-cell array SCA may be electrically connected to the peripheral circuit region PER through, for example, a through contact.

In FIG. 59, the sub-cell array SCA may be disposed on the substrate 100. The peripheral circuit region PER may be disposed on the sub-cell array SCA.

As an example, the peripheral circuit region PER may be electrically connected to the sub-cell array SCA through a through contact, for example. The peripheral circuit region PER may include a peripheral circuit wiring layer electrically connected to a circuit for operating the sub-cell array SCA. The wiring layer electrically connected to the sub-cell array SCA may be disposed to face the peripheral circuit wiring layer of the peripheral circuit region PER. The wiring layer electrically connected to the sub-cell array SCA may be electrically connected to the peripheral circuit wiring layer of the peripheral circuit region PER by using a wafer bonding method.

Although the embodiments of the present disclosure have been described with reference to the accompanying drawings, it will be apparent to those skilled in the art that the present disclosure may be fabricated in various forms without being limited to the above-described embodiments and may be embodied in other specific forms without departing from technical spirits and essential characteristics of the present disclosure. Thus, the above embodiments are to be considered in all respects as illustrative and not restrictive.

What is claimed is:

1. A semiconductor memory device comprising:
a first word line that extends on a substrate in a first direction that is parallel with an upper surface of the substrate;
a first semiconductor pattern that includes a first impurity region, a first channel region, and a second impurity region, wherein the first semiconductor pattern intersects the first word line and extends in a second direction that is parallel with the upper surface of the substrate and intersects the first direction;
a first bit line that extends in a third direction that is perpendicular to the upper surface of the substrate, wherein the first bit line is electrically connected to the first impurity region; and
a data storage element that is electrically connected to the second impurity region,
wherein the first word line includes a first conductive pattern including a plurality of grains, and
wherein a crystal direction of the plurality of grains is parallel with the upper surface of the substrate.

2. The semiconductor memory device of claim 1, wherein the crystal direction of the plurality of grains is the second direction.

3. The semiconductor memory device of claim 1, wherein the first word line extends around the first channel region.

4. The semiconductor memory device of claim 1, wherein the first semiconductor pattern includes a first surface and a second surface that is opposite to the first surface in the third direction, and
wherein the first word line includes a first sub-word line on the first surface and a second sub-word line on the second surface.

5. The semiconductor memory device of claim 1, wherein the first semiconductor pattern includes a first surface and a second surface that is opposite to the first surface in the third direction, and
wherein the first word line is on the first surface.

6. The semiconductor memory device of claim 1, further comprising:
a second semiconductor pattern that includes a third impurity region, a second channel region, and a fourth impurity region, wherein the second semiconductor pattern extends in the second direction and is spaced apart from the first semiconductor pattern in the first direction; and
a second bit line that extends in the third direction and is electrically connected to the third impurity region of the second semiconductor pattern,
wherein the first word line intersects the first channel region of the first semiconductor pattern and the second channel region of the second semiconductor pattern.

7. The semiconductor memory device of claim 1, further comprising:
a second semiconductor pattern that includes a third impurity region, a second channel region, and a fourth impurity region, wherein the second semiconductor pattern extends in the second direction and is spaced apart from the first semiconductor pattern in the third direction;
a second bit line that extends in the third direction and is electrically connected to the third impurity region of the second semiconductor pattern; and
a second word line that extends in the first direction and is spaced apart from the first word line in the third direction,
wherein the first word line intersects the first channel region of the first semiconductor pattern, and
wherein the second word line intersects the second channel region of the second semiconductor pattern.

8. The semiconductor memory device of claim 1, wherein a first width of the first word line in the first direction is different from a second width of the first semiconductor pattern in the first direction.

9. The semiconductor memory device of claim 8, wherein the first width of the first word line in the first direction is greater than the second width of the first semiconductor pattern in the first direction.

10. The semiconductor memory device of claim 8, wherein the first width of the first word line in the first direction is less than the second width of the first semiconductor pattern in the first direction.

11. The semiconductor memory device of claim 1, wherein the first word line further includes a second conductive pattern.

12. The semiconductor memory device of claim 11, wherein the first word line further includes an oxide layer between the first conductive pattern and the second conductive pattern.

13. The semiconductor memory device of claim 1, wherein the word line further includes a capping pattern on the first conductive pattern, and
the capping pattern includes at least one of metal silicide or metal silicon nitride.

14. A semiconductor memory device comprising:
a word line that extends on a substrate in a first direction that is parallel with an upper surface of the substrate, wherein the word line includes a first conductive pattern and a second conductive pattern;
a semiconductor pattern that intersects the word line and extends in a second direction that is parallel with the upper surface of the substrate and intersects the first direction, wherein the semiconductor pattern includes a first impurity region, a channel region, and a second impurity region;
a bit line that is electrically connected to the first impurity region and extends in a third direction that is perpendicular to the upper surface of the substrate; and
a data storage element that is electrically connected to the second impurity region,
wherein a first average size of first grains of the first conductive pattern is different from a second average size of second grains of the second conductive pattern.

15. The semiconductor memory device of claim 14, wherein the first conductive pattern is between the second conductive pattern and the bit line, and
wherein the first average size is greater than the second average size.

16. The semiconductor memory device of claim 14, wherein a length of at least one of the first grains of the first conductive pattern in the second direction is equal to a length of the first conductive pattern in the second direction.

17. A semiconductor memory device comprising:
a word line that extends on a substrate in a first direction that is parallel with an upper surface of the substrate;
semiconductor patterns that extend in a second direction that is parallel with the upper surface of the substrate, wherein the semiconductor patterns are arranged in the first direction, and each of the semiconductor patterns includes a first impurity region, a channel region, and a second impurity region;
a bit line that is electrically connected to the first impurity region; and
a data storage element that is electrically connected to the second impurity region,
wherein the word line intersects the semiconductor patterns and includes a first conductive pattern that has a columnar grain structure.

18. The semiconductor memory device of claim 17, wherein the word line extends around an outer circumferential surface of the semiconductor patterns,
wherein the word line includes a first surface and a second surface, which are opposite to each other in a third direction that is perpendicular to the upper surface of the substrate,
wherein the first surface includes a first recess that is recessed toward the second surface between adjacent ones among the semiconductor patterns in the third direction, and
wherein the second surface includes a second recess that is recessed toward the first surface between adjacent ones among the semiconductor patterns in the third direction.

19. The semiconductor memory device of claim 17, wherein the word line further includes a second conductive pattern that has a random grain structure, and
wherein the first conductive pattern is between the second conductive pattern and the bit line.

20. The semiconductor memory device of claim 17, further comprising a capping insulating pattern between the word line and the bit line,
wherein the word line further includes a capping pattern between the first conductive pattern and the capping insulating pattern, and
the capping pattern includes at least one of metal silicide or metal silicon nitride.
